(19) United States
(12) Patent Application Publication
(10) Pub. No.: US 2024/0324363 A1
(43) Pub. Date: Sep. 26, 2024

(54) DISPLAY APPARATUS

(71) Applicant: Samsung Display Co., LTD., Yongin-si (KR)

(72) Inventors: Junhyeong PARK, Yongin-si (KR); Kyungmin KIM, Yongin-si (KR)

(21) Appl. No.: 18/610,145

(22) Filed: Mar. 19, 2024

(30) Foreign Application Priority Data
Mar. 24, 2023 (KR) 10-2023-0038975
Jul. 11, 2023 (KR) 10-2023-0090028

(51) Int. Cl. H10K 59/131; H10K 59/80; H10K 59/88; H10K 102/00

(52) U.S. Cl. CPC H10K 59/131; H10K 59/873; H10K 59/88; H10K 2102/311

(57) ABSTRACT

A display apparatus includes a substrate, a first lower conductive pattern provided in an emission area of the substrate and defining a pixel opening, a light-emitting device in the pixel opening of the first lower conductive pattern, a first upper conductive pattern on the first lower conductive pattern, and a dummy pattern on the first upper conductive pattern, wherein the first upper conductive pattern includes a tip portion protruding from an upper surface of the first lower conductive pattern toward the pixel opening of the first lower conductive pattern, the first upper conductive pattern includes an outermost first upper conductive pattern disposed between the light-emitting device and a encapsulation area of the substrate in a plan view, and the dummy pattern is spaced apart from a second upper surface of the outermost first upper conductive pattern.

This application claims priority to Korean Patent Application No. 10-2023-0038975, filed on Mar. 24, 2023, and Korean Patent Application No. 10-2023-0090028, filed on Jul. 11, 2023, and all the benefits accruing therefrom under 35 U.S.C. § 119, the content of which in their entirety is herein incorporated by reference.

### BACKGROUND

### 1. Field

Embodiments relate to a display apparatus, and more particularly, to a stretchable display apparatus.

### 2. Description of the Related Art

With the development of display apparatuses visually displaying electrical signals, various display apparatuses having excellent characteristics, such as reduction in thickness, light-weight, and relatively low power consumption, are being introduced. For example, flexible display apparatuses that may be folded or rolled into a roll shape are being introduced. Recently, research and development on a stretchable display apparatus that may be changed into various shapes is being actively conducted.

### SUMMARY

Embodiments include a display apparatus having improved stretchable characteristics, flexible, rollable, and bendable characteristics and resolution and a method of manufacturing the display apparatus.

However, these features are exemplary, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a substrate including an emission area and an encapsulation area surrounding the emission area, a first lower conductive pattern provided in the emission area of the substrate and defining a pixel opening, a light-emitting device in the pixel opening of the first lower conductive pattern, a first upper conductive pattern on the first lower conductive pattern, and a dummy pattern on the first upper conductive pattern, wherein the first upper conductive pattern has a tip portion protruding from an upper surface of the first lower conductive pattern toward the pixel opening of the first lower conductive pattern, the first upper conductive pattern includes an outermost first upper conductive pattern disposed between the light-emitting device and the encapsulation area of the substrate in a plan view, the dummy pattern covers a first upper surface of the outermost first upper conductive pattern in the plan view and is spaced apart from a second upper surface of the outermost first upper conductive pattern, and the second upper surface of the outermost first upper conductive pattern is connected to the first upper surface of the outermost first upper conductive pattern and is disposed between the first upper surface of the outermost first upper conductive pattern and the encapsulation area of the substrate in the plan view.

In an embodiment, the tip portion of the first upper conductive pattern may be provided in the emission area of the substrate and may not be provided in the encapsulation area of the substrate.

In another embodiment, the display apparatus may further include a first inorganic encapsulation layer provided on the first upper conductive pattern and covering the light-emitting device, and a second inorganic encapsulation layer on the first inorganic encapsulation layer, wherein the first inorganic encapsulation layer may be disposed on the first upper surface of the outermost first upper conductive pattern but may be spaced apart from the second upper surface of the outermost first upper conductive pattern.

In another embodiment, the first inorganic encapsulation layer may be spaced apart from the encapsulation area of the substrate, and the second inorganic encapsulation layer may extend to the encapsulation area of the substrate.

In another embodiment, the second inorganic encapsulation layer may cover the second upper surface of the outermost first upper conductive pattern.

In another embodiment, the substrate may further include a connection area, and a portion of the encapsulation area is disposed between the emission area and the connection area, the light-emitting device, the first inorganic encapsulation layer, and the first lower conductive pattern may be spaced apart from the connection area of the substrate, and the second inorganic encapsulation layer may extend to the connection area of the substrate.

In another embodiment, the display apparatus may further include a second lower conductive pattern disposed in the connection area of the substrate and spaced apart from the first lower conductive pattern, and a second upper conductive pattern disposed on the second lower conductive pattern and spaced apart from the first upper conductive pattern, wherein the second lower conductive pattern may include a same material as that of the first lower conductive pattern, and the second upper conductive pattern may include a same material as that of the first upper conductive pattern.

In another embodiment, the display apparatus may further include an organic insulating layer between the substrate and the first lower conductive pattern, wherein the encapsulation area may include a first encapsulation area and a second encapsulation area, and the first encapsulation area is disposed between the emission area and the second encapsulation area, and the organic insulating layer may be provided in the emission area and the first encapsulation area of the substrate but is spaced apart from the second encapsulation area of the substrate.

In another embodiment, the display apparatus may further include an inorganic insulating layer between the organic insulating layer and the first lower conductive pattern, wherein the inorganic insulating layer may be provided in the emission area and the first encapsulation area of the substrate and may be spaced apart from the second encapsulation area of the substrate.

In another embodiment, the display apparatus may further include a first inorganic pattern provided between the outermost first upper conductive pattern and an end portion of the dummy pattern, wherein the dummy pattern may be provided on an inner side surface of the first inorganic pattern.

In another embodiment, the display apparatus may further include a second inorganic pattern provided on a sidewall of the organic insulating layer, wherein the second inorganic pattern may include a same material as that of the first inorganic pattern, and a thickness of the second inorganic pattern may be less than a thickness of the first inorganic pattern.

In an embodiment of the disclosure, a display apparatus includes a substrate including island areas and a connection area between the island areas, wherein each of the island areas includes an emission area and an encapsulation area, an inorganic insulating layer on the substrate, a first conductive pattern provided on the inorganic insulating layer in the island areas of the substrate and defining pixel openings, light-emitting devices provided in the pixel openings of the first conductive pattern, a first inorganic encapsulation layer sealing the light-emitting devices in the emission area of the substrate, and a second inorganic encapsulation layer on the first inorganic encapsulation layer, wherein the inorganic insulating layer includes a second inorganic encapsulation layer on the first inorganic encapsulation layer, and a second inorganic insulating layer provided in the connection area of the substrate and spaced apart from the first inorganic insulating layer, wherein the first inorganic encapsulation layer is spaced apart from the encapsulation area and the connection area of the substrate, and the second inorganic encapsulation layer is provided in the emission area, the encapsulation area, and the connection area of the substrate.

In another embodiment, a first thickness of the first inorganic encapsulation layer may be greater than a second vertical thickness of the second inorganic encapsulation layer and a third thickness of the first inorganic insulating layer, and the second vertical thickness may be greater than the third thickness.

In another embodiment, the display apparatus may further include a second conductive pattern provided in the connection area of the substrate and covering the second inorganic insulating layer, wherein the second conductive pattern may be spaced apart from the first conductive pattern and include a same material as that of the first conductive pattern.

In another embodiment, a plurality of second conductive patterns may be provided in the connection area of the substrate, and the plurality of second conductive patterns may be spaced apart from each other.

In another embodiment, a plurality of second inorganic insulating layers may be provided in the connection area of the substrate, and the plurality of second inorganic insulating layers may be spaced apart from each other, and the plurality of second conductive patterns may be respectively provided on the plurality of second inorganic insulating layers.

In another embodiment, the display apparatus may further include an organic insulating layer disposed in the emission area and the encapsulation area of the substrate, and a second inorganic pattern provided on a sidewall of the organic insulating layer, wherein the first inorganic insulating layer may be disposed on the organic insulating layer, and the second inorganic pattern may not extend onto an upper surface of the first inorganic insulating layer.

In another embodiment, the second inorganic encapsulation layer may extend onto the sidewall of the organic insulating layer, and the second inorganic pattern may be between the sidewall of the organic insulating layer and the second inorganic encapsulation layer.

In another embodiment, the second inorganic encapsulation layer may include a second vertical thickness from the upper surface of the first conductive pattern, and a second horizontal thickness from the sidewall of the second inorganic pattern, wherein the second horizontal thickness of the second inorganic encapsulation layer may be greater than a thickness of the second inorganic pattern.

In another embodiment, a sum of a first thickness of the first inorganic encapsulation layer and the second vertical thickness of the second inorganic encapsulation layer may be greater than a sum of the second horizontal thickness of the second inorganic encapsulation layer and the thickness of the second inorganic pattern.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of a display apparatus;

FIG. 2 is an equivalent circuit diagram of an embodiment of a pixel;

FIG. 3A is an enlarged plan view of an embodiment of a portion of a display area, that is, a region I of FIG. 1, of the display apparatus;

FIG. 3B is a cross-sectional view of the display apparatus taken along line II-II′ of FIG. 3A;

FIG. 3C is an enlarged view of a region A of FIG. 3B;

FIG. 3D is a cross-sectional view of the display apparatus taken along line III-III′ of FIG. 3A;

FIGS. 4A and 4B are diagrams for explaining display apparatuses according to different embodiments;

FIG. 5 is a cross-sectional view for explaining another embodiment of a display apparatus;

FIG. 6A is an enlarged plan view of another embodiment of a portion of a display area of a display apparatus;

FIG. 6B is a cross-sectional view of the display apparatus taken along line II-II′ of FIG. 6A;

FIG. 6C is a cross-sectional view of the display apparatus taken along line III-III′ of FIG. 6A;

FIG. 7A is an enlarged plan view of another embodiment of a portion of a display area of a display apparatus;

FIG. 7B is a cross-sectional view of the display apparatus taken along line III-III′ of FIG. 7A; and

FIGS. 8A to 14B are diagrams for explaining an embodiment of a method of manufacturing a display apparatus.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When an illustrative embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” In addition, “at least one of A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

In the disclosure, like reference numerals in the drawings denote like elements. Hereinafter, a display apparatus in embodiments and a method of manufacturing the display apparatus are described.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

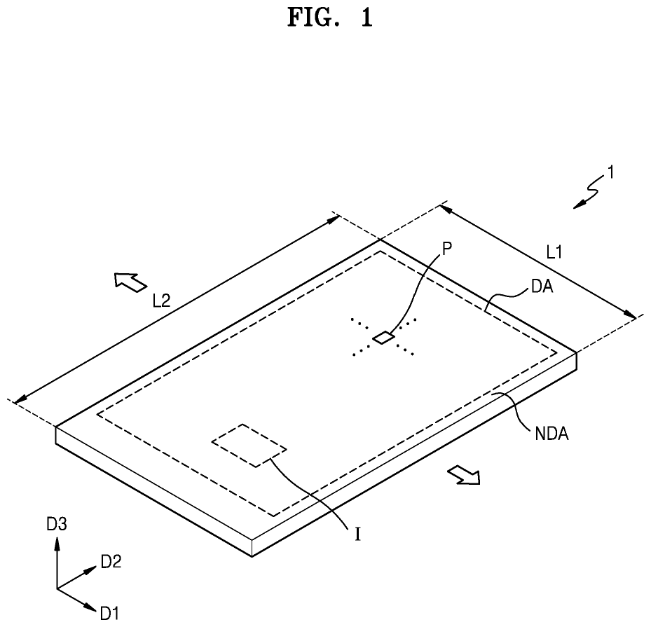

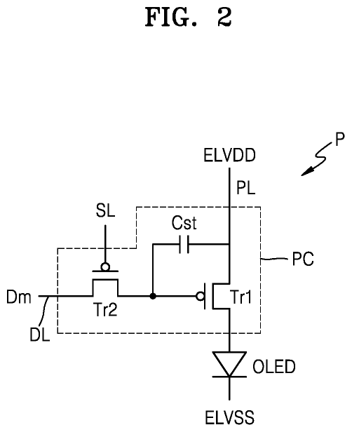

FIG. 1 is a perspective view schematically illustrating an embodiment of a display apparatus. FIG. 2 is an equivalent circuit diagram of an embodiment of a pixel.

Referring to FIGS. 1 and 2, a display apparatus 1 in an embodiment may include a display area DA and a peripheral area NDA. The peripheral area NDA may be disposed outside the display area DA to surround the display area DA. Driving circuit units and various lines which transfer electrical signals to the display area DA may be disposed in the peripheral area NDA. The display apparatus 1 may provide a predetermined image by light emitted from a plurality of pixels P arranged in the display area DA.

Each of the plurality of pixels P may include a display element, such as an organic light-emitting device or an inorganic light-emitting device, and may emit red, green, blue, or white light, for example, but is not limited thereto, and may emit various other color lights. That is, each of the plurality of pixels P may further include a pixel circuit PC including first and second thin-film transistors Tr1 and Tr2 and a storage capacitor Cst, which is connected to the display element, as shown in FIG. 2. The pixel circuit PC may be connected to a scan line SL, a data line DL crossing the scan line SL, and a driving voltage line PL.

Each of the plurality of pixels P may emit light by driving the pixel circuit PC, and the display area DA provides a predetermined image through light emitted from the plurality of pixels P. The pixel P in the disclosure may be defined as an emission area emitting any one color of red, green, blue, and white light as described above.

The peripheral area NDA is an area in which the plurality of pixels P is not arranged and may not provide an image. A printed circuit board or a terminal unit may be disposed in the peripheral area NDA. The printed circuit board may include a built-in driving circuit unit, a power supply line, and a driving circuit unit in order to drive the pixels P. The terminal unit may be connected to a driver integrated circuit (“IC”).

In each of the plurality of pixels P, a display element (e.g., a light-emitting device such as an organic light-emitting diode) is connected to the pixel circuit PC. As shown in FIG. 2, the pixel circuit PC may include the first thin-film transistor Tr1, the second thin-film transistor Tr2, and the storage capacitor Cst. The organic light-emitting diode OLED may emit red, green, or blue light or may emit red, green, blue, or white light, for example, but is not limited thereto, and may emit various other color lights.

The second thin-film transistor Tr2 is a switching thin-film transistor, which may be connected to the scan line SL and the data line DL. The second thin-film transistor Tr2 may transfer, to the first thin-film transistor Tr1, a data voltage Dm input from the data line DL according to a switching voltage input from the scan line SL.

The storage capacitor Cst may be connected to the second thin-film transistor Tr2 and the driving voltage line PL. The storage capacitor Cst may store a voltage corresponding to a difference between a voltage received from the second thin-film transistor Tr2 and a first power supply voltage ELVDD supplied to the driving voltage line PL.

The first thin-film transistor Tr1 is a driving thin-film transistor, which may be connected to the driving voltage line PL and the storage capacitor Cst. The first thin-film transistor Tr1 may control a driving current flowing from the driving voltage line PL to the organic light-emitting diode OLED in accordance with a voltage value stored in the storage capacitor Cst. The organic light-emitting diode OLED may emit light having a predetermined brightness according to the driving current. An opposite electrode (e.g., a cathode) of the organic light-emitting diode OLED may receive a second power supply voltage ELVSS. However, the disclosure is not limited thereto, and the opposite electrode (e.g., a cathode) of the organic light-emitting diode OLED may receive a ground voltage.

Although FIG. 2 shows that the pixel circuit PC includes two transistors (that is, the first and second thin-film transistors Tr1 and Tr2) and one storage capacitor Cst, the pixel circuit PC may include three or more transistors.

The display apparatus 1 may include a first side L1 extending in a first direction D1 and a second side L2 extending in a second direction D2. Each of the first side L1 and the second side L2 may be an edge of the display apparatus 1. The second direction D2 may cross the first direction D1. A third direction D3 may cross a plane defined by the first direction D1 and the second direction D2. The third direction D3 may be a vertical direction.

The display apparatus 1 may be a stretchable display apparatus. As indicated by the arrows, when tensile force is applied to the display apparatus 1 in the first direction D1 and an opposite direction of the first direction D1, the display apparatus 1 may be stretched in the first direction D1 and the opposite direction of the first direction D1. In this case, the first side L1 of the display apparatus 1 in a state having tensile force applied may be longer than the first side L1 before the tensile force is applied. In another embodiment, when contraction force is applied to the display apparatus 1 in the first direction D1 and the opposite direction of the first direction D1, the display apparatus 1 may be contracted in the first direction D1 and the opposite direction of the first direction D1. In this case, the first side L1 of the display apparatus 1 in a state having contraction force applied may be less than the first side L1 before the contraction force is applied.

In another embodiment, when tensile force is applied to the display apparatus 1 in the second direction D2 and an opposite direction of the second direction D2, the display apparatus 1 may be stretched in the second direction D2 and the opposite direction of the second direction D2. The second side L2 of the display apparatus 1 in a state having tensile force applied may be longer than the second side L2 before the tensile force is applied. In another embodiment, when contraction force is applied to the display apparatus 1 in the second direction D2 and the opposite direction of the second direction D2, the display apparatus 1 may be contracted in the second direction D2 and the opposite direction of the second direction D2. As described above, when tensile force or contraction force is applied to the display apparatus 1, the display apparatus 1 may be changed into various shapes.

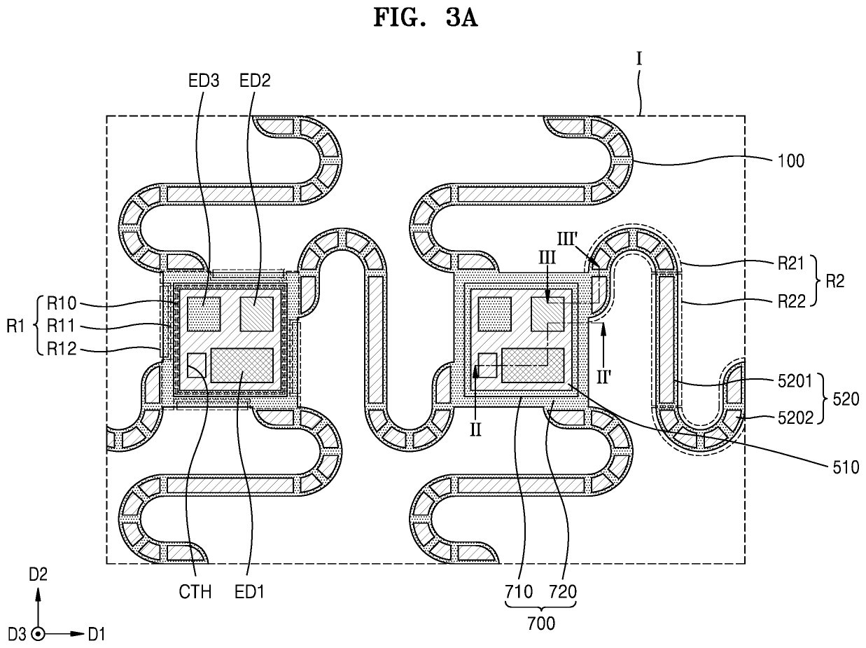

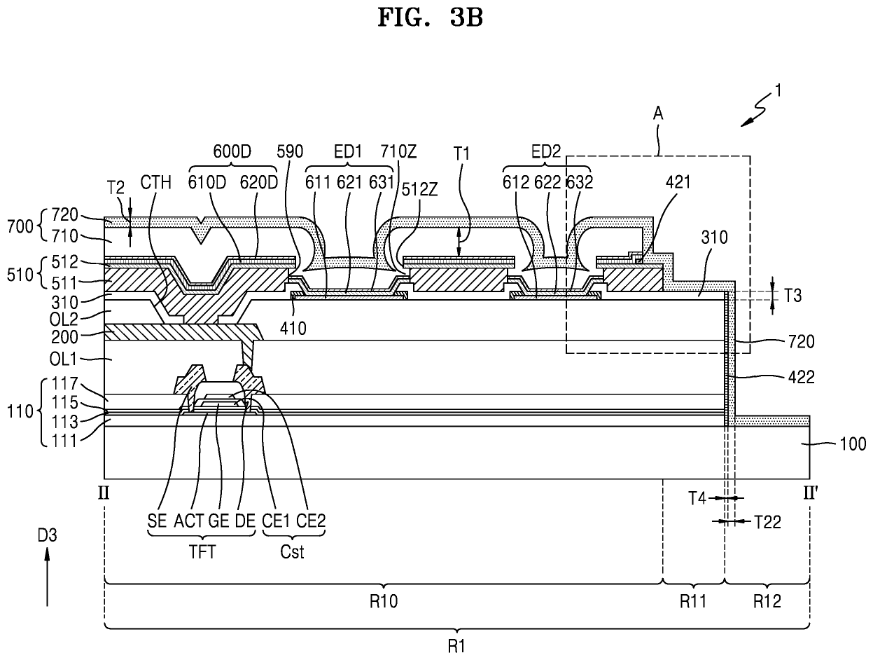

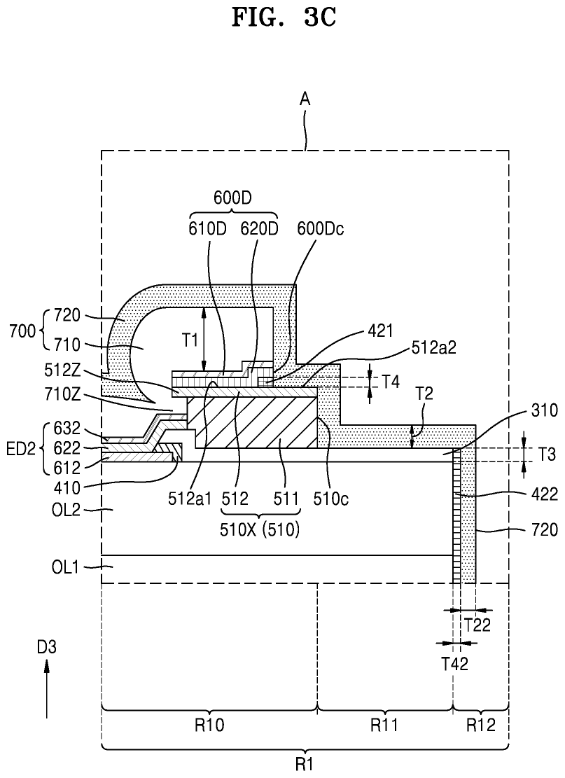

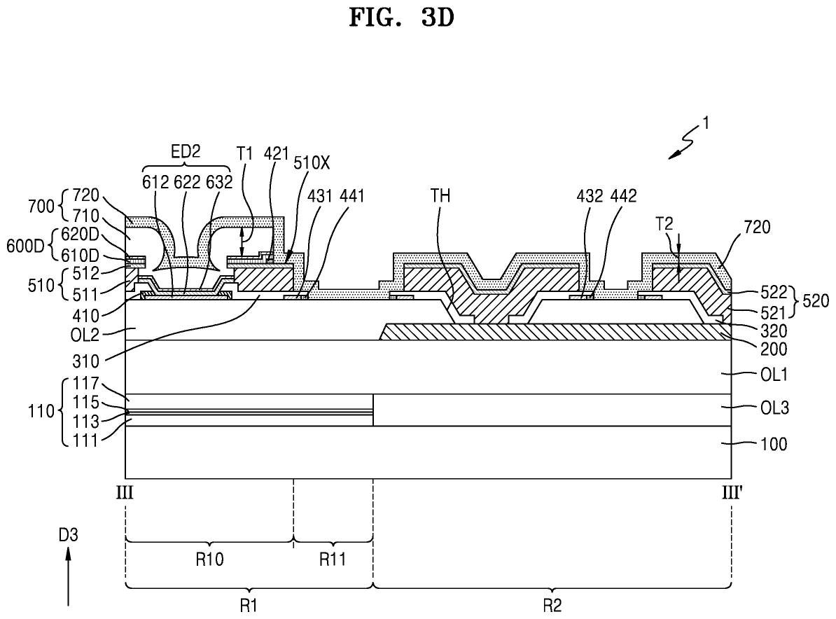

FIG. 3A is an enlarged plan view of a portion of a display area, that is, a region I of FIG. 1, of the display apparatus. FIG. 3B is a cross-sectional view of an embodiment of the display apparatus taken along line II-II′ of FIG. 3A. FIG. 3C is an enlarged view of a region A of FIG. 3B. FIG. 3D is a cross-sectional view of the display apparatus taken along line III-III′ of FIG. 3A.

Referring to FIGS. 3A, 3B, 3C, and 3D, the display apparatus 1 may include a substrate 100, a pixel layer, a line pattern 200, a first conductive pattern 510, second conductive patterns 520, an organic insulating layer, a first inorganic insulating layer 310, a second inorganic insulating layer 320, a first inorganic pattern 421, a second inorganic pattern 422, and an encapsulation layer 700. The pixel layer may include a pixel circuit layer and a display element layer. The organic insulating layer may include a first organic insulating layer OL1 and a second organic insulating layer OL2.

As shown in FIG. 3A, the substrate 100 of the display apparatus 1 may include an island area R1 and a connection area R2. The island area R1 and the connection area R2 of the substrate 100 may be included in the display area DA of FIG. 1. A plurality of island areas R1 of the substrate 100 may be provided. Each of the plurality of island areas R1 of the substrate 100 may include an emission area R10, a first encapsulation area R11, and a second encapsulation area R12. The emission area R10 may be provided at a center portion of the island area R1 in a plan view.

The display element layer may include a first light-emitting device ED1, a second light-emitting device ED2, and a third light-emitting device ED3. The first light-emitting device ED1, the second light-emitting device ED2, and the third light-emitting device ED3 may be arranged in the emission area R10 of the substrate 100. The first light-emitting device ED1, the second light-emitting device ED2, and the third light-emitting device ED3 may be arranged to be spaced apart from each other and may emit light having different wavelengths from each other. In an embodiment, the first light-emitting device ED1, the second light-emitting device ED2, and the third light-emitting device ED3 may respectively emit blue light, red light, and green light. That is, the first light-emitting device ED1, the second light-emitting device ED2, and the third light-emitting device ED3 may respectively correspond to a blue sub-pixel area, a red sub-pixel area, and a green sub-pixel area, for example, but the disclosure is not limited thereto. A planar arrangement of first light-emitting device ED1, the second light-emitting device ED2, and the third light-emitting device ED3 may be variously changed. Unlike shown in the drawing, the display apparatus 1 may further include a fourth light-emitting device (not shown). The fourth light-emitting device may be disposed in the emission area R10 of the substrate 100 and may emit white light.

The first encapsulation area R11 of the substrate 100 may be disposed between an outer wall of the island area R1 of the substrate 100 and the emission area R10. The first encapsulation area R11 of the substrate 100 may surround the emission area R10 in a plan view. The first encapsulation area R11 of the substrate 100 may be provided between the emission area R10 and the second encapsulation area R12 to be described below and between the emission area R10 and the connection area R2 to be described below.

The second encapsulation area R12 may be disposed between the first encapsulation area R11 and outer walls of the substrate 100. The second encapsulation area R12 may be disposed outside the first encapsulation area R11 in a plan view.

The connection area R2 of the substrate 100 may be disposed between the island areas R1. The island areas R1 of the substrate 100 may be connected to each other through the connection area R2. The connection area R2 may be disposed outside the first encapsulation area R11, for example. Any one island area R1 may be connected to a plurality of connection areas R2. At least one of the connection areas R2 may include a straight connection area R22 and a curved connection area R21. The straight connection area R22 may extend in one direction in a plan view and may have a bar shape. The curved connection area R21 may be connected to the straight connection area R22. In an embodiment, the curved connection area R21 may be disposed between the straight connection area R22 and the island area R1, for example. The connection area R2 of the substrate 100 and components in the connection area R2 may be easily crooked, bent, or folded.

The first conductive pattern 510 and the second conductive patterns 520 may be disposed above the substrate 100. The first conductive pattern 510 may be provided in the emission area R10 of the substrate 100 in a plan view, may be directly adjacent to the first encapsulation area R11, and may be spaced apart the second encapsulation area R12, and the connection area R2. Any one of the first conductive pattern 510 and the second conductive patterns 520 may also not be provided in the first encapsulation area R11 and the second encapsulation area R12 of the substrate 100.

A plurality of second conductive patterns 520 may be provided in the connection area R2 of the substrate 100 and may be spaced apart from the island area R1. The second conductive patterns 520 may be spaced apart from the first conductive pattern 510. Accordingly, the connection area R2 of the substrate 100 and components in the connection area R2 may have improved stretchable characteristics. Thus, the display apparatus 1 may have improved stretchable, flexible, rollable, and bendable characteristics.

The second conductive patterns 520 may include a first sub conductive pattern 5201 and second sub conductive patterns 5202. A single first sub conductive pattern 5201 may be disposed in any one straight connection area R22. The first sub conductive pattern 5201 may have a shape corresponding to the straight connection area R22. In an embodiment, the first sub conductive pattern 5201 may extend in one direction in a plan view and may have a bar shape, for example.

A plurality of second sub conductive patterns 5202 may be arranged in any one curved connection area R21. The plurality of second sub conductive patterns 5202 may be spaced apart from each other in the any one curved connection area R21. A second sub conductive pattern 5202 may be horizontally spaced apart from the first sub conductive pattern 5201. As the second sub conductive patterns 5202 in the curved connection area R21 are spaced apart from each other, the curved connection area R21 of the substrate 100 of the display apparatus 1 may show improved stretchable characteristics.

The substrate 100 may include a glass material or a polymer resin. In an embodiment, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or the like, for example. Accordingly, the substrate 100 may have stretchable, flexible, rollable, or bendable characteristics. Hereinafter, components in the emission area R10 of the substrate 100 are described.

The pixel circuit layer, the first organic insulating layer OL1, the second organic insulating layer OL2, the line pattern 200, the first conductive pattern 510, the first inorganic insulating layer 310, the first inorganic pattern 421, the first and second light-emitting devices ED1 and ED2, and the encapsulation layer 700 may be provided in the emission area R10 of the substrate 100.

The pixel circuit layer may be disposed on the substrate 100. The pixel circuit layer may include a stacked structure 110 and the pixel circuit PC (refer to FIG. 2). In an embodiment, the pixel circuit layer may include the stacked structure 110, a thin-film transistor TFT, and the storage capacitor Cst, for example. The stacked structure 110 may include a buffer layer 111, a gate insulating layer 113, a first inter-insulating film 115, and a second inter-insulating film 117.

The buffer layer 111 may be provided on the substrate 100. The buffer layer 111 may prevent impurities from penetrating a semiconductor layer ACT of the thin-film transistor TFT. The buffer layer 111 may include an inorganic insulating material, such as silicon nitride, silicon oxynitride, and/or silicon oxide, and may be a single layer or a multi-layer, each including the inorganic insulating material stated above.

The thin-film transistor TFT may include the semiconductor layer ACT, a gate electrode GE, a source electrode SE, and a drain electrode DE. The semiconductor layer ACT may include amorphous silicon, polycrystalline silicon, or an organic semiconductor material. The semiconductor layer ACT may include a channel area and impurity areas. The impurity areas may be respectively arranged on opposite sides of the channel area. Any one of the impurity areas may be a source area and the other one may correspond to a drain area.

The gate insulating layer 113 may be between the semiconductor layer ACT and the gate electrode GE. The gate insulating layer 113 may secure insulation between the semiconductor layer ACT and the gate electrode GE. The gate insulating layer 113 may include an inorganic material such as silicon oxide (SiOₓ), silicon nitride (SiNₓ), and/or silicon oxynitride (SiOₓN_{y}). The gate insulating layer 113 may be formed through chemical vapor deposition (“CVD”) or atomic layer deposition (“ALD”).

The gate electrode GE may be disposed to be vertically spaced apart from the semiconductor layer ACT. The gate electrode GE may include a conductive material including molybdenum, aluminum, copper, titanium, or the like and may include a single-layered structure or a multi-layered structure, each including the above material.

The storage capacitor Cst may include a lower electrode CE1 and an upper electrode CE2, which overlap each other. In an embodiment, the lower electrode CE1 of the storage capacitor Cst may include the gate electrode GE of the thin-film transistor TFT. In an embodiment, the gate electrode GE of the thin-film transistor TFT may be the same component as the lower electrode CE1 of the storage capacitor Cst, for example.

The first inter-insulating film 115 may be disposed between the lower electrode CE1 and the upper electrode CE2 of the storage capacitor Cst, and the second inter-insulating film 117 may be disposed on the upper electrode CE2 of the storage capacitor Cst. The first inter-insulating film 115 and the second inter-insulating film 117 may each include an inorganic insulating material, such as silicon oxide, silicon nitride, and silicon oxynitride, and may include a single-layered structure or a multi-layered structure, each including the above inorganic insulating material.

The source electrode SE and the drain electrode DE may be disposed on the second inter-insulating film 117. In some embodiments, any one of the source electrode SE and the drain electrode DE may be omitted. Each of the source electrode SE and the drain electrode DE may include a conductive material including molybdenum, aluminum, copper, titanium, or the like and may include a single-layered structure or a multi-layered structure, each including the above material. In an embodiment, the source electrode SE and the drain electrode DE may each have a multi-layered structure including titanium layer/aluminum layer/titanium layer (Ti/Al/Ti), for example.

The organic insulating layer may include the first organic insulating layer OL1 and the second organic insulating layer OL2. The first organic insulating layer OL1 may be disposed on the second inter-insulating film 117 to cover the source electrode SE and the drain electrode DE. The first organic insulating layer OL1 may function as a planarization layer. In an embodiment, the first organic insulating layer OL1 may include acrylic resin, benzocyclobutene (“BCB”), polyimide, or hexamethyldisiloxane (“HMDSO”), for example.

The line pattern 200 may be disposed on the first organic insulating layer OL1. The line pattern 200 may be provided in the island area R1 and the connection area R2 of the substrate 100. In an embodiment, the line pattern 200 may extend from the emission area R10 of the substrate 100 to the connection area R2 in FIGS. 3A and 3D, for example. Accordingly, the line pattern 200 in the emission area R10 of the substrate 100 may be connected to the line pattern 200 in the connection area R2. The line pattern 200 may function as a line to which a common voltage, such as the second power supply voltage ELVSS of FIG. 2, is applied, but the disclosure is not limited thereto. The line pattern 200 in the emission area R10 of the substrate 100 may be connected to the source electrode SE or the drain electrode DE of the thin-film transistor TFT by penetrating the first organic insulating layer OL1. The line pattern 200 may include a conductive material including molybdenum, aluminum, copper, titanium, or the like and may include a single-layered structure or a multi-layered structure, each including the above material. In an embodiment, the line patterns 200 may each have a multi-layered structure including titanium layer/aluminum layer/titanium layer (Ti/Al/Ti), for example.

The second organic insulating layer OL2 may be disposed on the first organic insulating layer OL1 to cover the line pattern 200. A contact hole CTH may be defined in the second organic insulating layer OL2. The contact hole CTH may be defined in the emission area R10 of the substrate 100 and may expose an upper surface of the line pattern 200. The second organic insulating layer OL2 may include acrylic resin, BCB, polyimide, or HMDSO.

The first light-emitting device ED1 and the second light-emitting device ED2 may be disposed on the second organic insulating layer OL2. The first light-emitting device ED1 may include a first lower electrode 611, a first intermediate layer 621, and a first upper electrode 631. The second light-emitting device ED2 may include a second lower electrode 612, a second intermediate layer 622, and a second upper electrode 632. Although not illustrated in FIG. 3B, the third light-emitting device ED3 (refer to FIG. 3A) may be disposed on the second organic insulating layer OL2 and may include a third upper electrode, a third intermediate layer, and a third lower electrode. As the first light-emitting device ED1, the second light-emitting device ED2, and the third light-emitting device ED3 have substantially the same or similar structures, hereinafter, the first light-emitting device ED1 and the second light-emitting device ED2 are mainly described.

The first lower electrode 611 and the second lower electrode 612 may be disposed on the second organic insulating layer OL2. The first lower electrode 611 and the second lower electrode 612 may be arranged to be horizontally spaced apart for each other. Each of the first lower electrode 611 and the second lower electrode 612 may be a transparent electrode, a semi-transparent electrode, or a reflective electrode. When each of the first lower electrode 611 and the second lower electrode 612 is a transparent electrode or a semi-transparent electrode, each of the first lower electrode 611 and the second lower electrode 612 may include a transparent conductive oxide. The transparent conductive oxide may include indium tin oxide (“ITO”), indium zinc oxide (“IZO”), zinc oxide (ZnO), indium oxide (In₂O₃), indium gallium oxide (“IGO”), or aluminum zinc oxide (“AZO”), for example. When each of the first lower electrode 611 and the second lower electrode 612 is a reflective electrode, each of the first lower electrode 611 and the second lower electrode 612 may include a reflective film and an oxide film. The reflective film may include Ag, Mg, Al, Pt, Pd, Au, Ni, Nd, Ir, Cr, or any combinations thereof. The oxide film may be provided on the reflective film and may include ITO, IZO, ZnO, or In₂O₃. In an embodiment, at least one of the first lower electrode 611 and the second lower electrode 612 may include an ITO layer, an Ag layer, and an ITO layer, which are sequentially stacked.

The first intermediate layer 621 may be provided on the first lower electrode 611, and the second intermediate layer 622 may be provided on the second lower electrode 612. The second intermediate layer 622 may be disposed to be horizontally spaced apart from the first intermediate layer 621. The first intermediate layer 621 may include a first emission layer and a first functional layer. The second intermediate layer 622 may include a second emission layer and a second functional layer. The second emission layer and the first emission layer may include different materials from each other. Each of the first and second emission layers may include a polymer organic material or a low-molecular-weight organic material, which emits light of a predetermined color (red, green, or blue). In another embodiment, each of the first and second emission layers may include an inorganic material or quantum dots. The first functional layer may be provided on an upper or lower surface of the first emission layer, and the second functional layer may be provided on an upper or lower surface of the second emission layer. The second functional layer may include the same material as that of the first functional layer and may be formed by a single process with the first functional layer. Each of the first functional layer and the second functional layer may be a single layer or a multi-layer. In an embodiment, the first functional layer and the second functional layer may each include a hole transport layer (“HTL”), a hole injection layer (“HIL”), an electron transport layer (“ETL”), and/or an electron injection layer (“EIL”), for example.

The first upper electrode 631 may be provided on the first intermediate layer 621. The second upper electrode 632 may be provided on the second intermediate layer 622. The second upper electrode 632 may be disposed to be horizontally spaced apart from the first upper electrode 631. Each of the first upper electrode 631 and the second upper electrode 632 may include a conductive material having a relatively low work function. Each of the first upper electrode 631 and the second upper electrode 632 may be a transparent electrode or a semi-transparent electrode. In this case, each of the first upper electrode 631 and the second upper electrode 632 may include silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or alloys thereof. The first upper electrode 631 and the second upper electrode 632 may further include an oxide layer, and the oxide layer may be provided on the transparent electrode or the semi-transparent electrode. The oxide layer may include ITO, IZO, ZnO, or In₂O₃.

The first inorganic insulating layer 310 may be disposed on the second organic insulating layer OL2. The first inorganic insulating layer 310 may be a portion of a bank layer. The first inorganic insulating layer 310 may be provided on an upper surface and a sidewall of an edge portion of the first lower electrode 611. The first inorganic insulating layer 310 may increase a distance between the edge portion of the first lower electrode 611 and the first upper electrode 631 to prevent an arc from being generated therebetween. Similarly, the first inorganic insulating layer 310 may be provided on an upper surface and a sidewall of an edge portion of the second lower electrode 612. The first inorganic insulating layer 310 may increase a distance between the edge portion of the second lower electrode 612 and the second upper electrode 632. Pixel openings 590 respectively corresponding to the first lower electrode 611 and the second lower electrode 612 may be defined in the first inorganic insulating layer 310. The first inorganic insulating layer 310 may further extend onto inner sidewalls of the contact hole CTH. The first inorganic insulating layer 310 may expose at least a portion of an upper surface of the line pattern 200. The first inorganic insulating layer 310 may include silicon oxide, silicon nitride, and/or silicon oxynitride. The first inorganic insulating layer 310 may be a single layer or a multi-layer.

The display apparatus 1 may further include electrode protective patterns 410 in the emission area R10 of the substrate 100. The electrode protective patterns 410 may be provided between the first lower electrode 611 and the first inorganic insulating layer 310 and between the second lower electrode 612 and the first inorganic insulating layer 310. At least one of the electrode protective patterns 410 may cover the upper surface and sidewall of the edge portion of the first lower electrode 611, and another one of the electrode protective patterns 410 may cover the upper surface and sidewall of the edge portion of the second lower electrode 612. The electrode protective patterns 410 may prevent damage to the first lower electrode 611 and the second lower electrode 612 in an etching process or ashing process for manufacturing the display apparatus 1. The electrode protective patterns 410 may include a material having etch selectivity with respect to the first and second lower electrodes 611 and 612. The electrode protective patterns 410 may include a transparent conductive oxide such as IZO and/or indium gallium zinc oxide (“IGZO”).

The first conductive pattern 510 may be disposed on the first inorganic insulating layer 310 in the emission area R10 of the substrate 100. The first conductive pattern 510 may be another portion of a bank layer. In an embodiment, the first conductive pattern 510 may be a metal bank layer. The pixel openings 590 may be defined in the first conductive pattern 510, for example. The first to third light-emitting devices ED1, ED2, and ED3 may be provided in the pixel openings 590. The pixel openings 590 may respectively expose upper surfaces of the first to third light-emitting devices ED1, ED2, and ED3. The pixel openings 590 may correspond to openings of a first lower conductive pattern 511.

The first conductive pattern 510 may include the first lower conductive pattern 511 and a first upper conductive pattern 512. The first upper conductive pattern 512 may be disposed on an upper surface of the first lower conductive pattern 511 and may include a different metal from the first lower conductive pattern 511. In an embodiment, the first upper conductive pattern 512 may include a metal having etch selectivity different from that of the first lower conductive pattern 511, for example. In an embodiment, the first lower conductive pattern 511 may include Al or molybdenum (Mo) and the first upper conductive pattern 512 may include titanium (Ti) or tantalum (Ta), for example.

The first upper conductive pattern 512 may have a tip portion 512Z. The tip portion 512Z of the first upper conductive pattern 512 may not vertically overlap the upper surface of the first lower conductive pattern 511. The tip portion 512Z of the first upper conductive pattern 512 may be a portion protruding laterally toward a corresponding pixel opening 590. In an embodiment, a portion of the first lower conductive pattern 511 is horizontally removed so that a sidewall of the first lower conductive pattern 511 may have an undercut structure. Accordingly, the tip portion 512Z of the first upper conductive pattern 512 may be formed. The tip portion 512Z of the first upper conductive pattern 512 is provided in the emission area R10 of the substrate 100 but may not be provided in the first and second encapsulation areas R11 and R12 of the substrate 100.

A plurality of tip portions 512Z of the first upper conductive pattern 512 may be provided in the emission area R10 of the substrate 100. The tip portions 512Z of the first upper conductive pattern 512, which are adjacent to any one of the pixel openings 590, may face each other. The tip portions 512Z of the first upper conductive pattern 512, which are adjacent to any one of the pixel openings 590, may form a horizontally symmetrical structure around a center area of the pixel opening 590.

The display apparatus 1 may further include a dummy pattern 600D. The dummy pattern 600D is provided in the emission area R10 of the substrate 100 but may not be provided in the first encapsulation area R11 and the second encapsulation area R12. The dummy pattern 600D may be disposed on the first upper conductive pattern 512. In an embodiment, the dummy pattern 600D may cover an upper surface of the tip portion 512Z of the first upper conductive pattern 512, for example. The dummy pattern 600D may be spaced apart from the first light-emitting device ED1 by the tip portion 512Z of the first upper conductive pattern 512.

The dummy pattern 600D may include a dummy intermediate layer 610D and a dummy upper electrode 620D. The dummy intermediate layer 610D may include the same material as that of the first functional layer of the first intermediate layer 621 and the second functional layer of the second intermediate layer 622. The dummy intermediate layer 610D may have the same thickness as that of the first functional layer of the first intermediate layer 621 and the second functional layer of the second intermediate layer 622. The dummy upper electrode 620D may be disposed on the dummy intermediate layer 610D. The dummy upper electrode 620D may include the same material as that of the first upper electrode 631 and the second upper electrode 632. The dummy upper electrode 620D may include the same thickness as that of the first upper electrode 631 and the second upper electrode 632.

The encapsulation layer 700 may be disposed on the first conductive pattern 510, the first light-emitting device ED1, and the second light-emitting device ED2. The encapsulation layer 700 may seal the first light-emitting device ED1 and the second light-emitting device ED2. Although not illustrated in FIG. 3B, the encapsulation layer 700 may further seal the third light-emitting device ED3 (refer to FIG. 3A).

The encapsulation layer 700 may include a first inorganic encapsulation layer 710 and a second inorganic encapsulation layer 720. The first inorganic encapsulation layer 710 may cover the dummy pattern 600D, the first upper electrode 631, and the second upper electrode 632. The first inorganic encapsulation layer 710 may include an inorganic insulating material, such as aluminum oxide, titanium oxide, tantalum oxide, hafnium oxide, zinc oxide, silicon oxide, silicon nitride, and/or silicon oxynitride. The first inorganic encapsulation layer 710 may include a material having excellent step coverage. Accordingly, the first inorganic encapsulation layer 710 may include inorganic bonding portions 710Z. The inorganic bonding portions 710Z of the first inorganic encapsulation layer 710 may be in direct contact with a lower surface of the tip portion 512Z of the first upper conductive pattern 512 and a side surface of the first lower conductive pattern 511 to seal well the first upper conductive pattern 512 and the first lower conductive pattern 511. Accordingly, the first inorganic encapsulation layer 710 may prevent impurities from penetrating into the first light-emitting device ED1 and the second light-emitting device ED2. The first inorganic encapsulation layer 710 may have a first thickness T1. The first thickness T1 may be relatively large. In an embodiment, the first thickness T1 may be about 10,000 angstroms (Å) to about 14,000 Å, for example. The first thickness T1 may be measured from an upper surface of the dummy pattern 600D, but the disclosure is not limited thereto, the first thickness T1 may also be measured from an upper surface of the first conductive pattern 510.

The second inorganic encapsulation layer 720 may be disposed on the first inorganic encapsulation layer 710 to cover the first inorganic encapsulation layer 710. The second inorganic encapsulation layer 720 may have a second vertical thickness T2. The second vertical thickness T2 may be less than the first thickness T1. In an embodiment, the second vertical thickness T2 may be about 5,000 Å to about 9,000 Å, for example. The second vertical thickness T2 may be measured from an upper surface of the first inorganic encapsulation layer 710, from an upper surface of the first inorganic insulating layer 310 in the first encapsulation area R11 of the substrate 100 to be described below, or from an upper surface of the first upper conductive pattern 512 or the second organic insulating layer OL2 in the connection area R2. The second inorganic encapsulation layer 720 may include a different material from that of the first inorganic encapsulation layer 710, but the disclosure is not limited thereto. In an embodiment, the second inorganic encapsulation layer 720 may include an inorganic insulating material such as aluminum oxide, titanium oxide, tantalum oxide, hafnium oxide, zinc oxide, silicon oxide, silicon nitride, and/or silicon oxynitride, for example.

Hereinafter, components in an edge area of the emission area R10 of the substrate 100 are described in more detail with reference to FIG. 3C. At this time, the edge area of the emission area R10 of the substrate 100 may be adjacent to the first encapsulation area R11 in a plan view. In an embodiment, the edge area of the emission area R10 of the substrate 100 may be disposed between the center area of the emission area R10 and the first encapsulation area R11, for example.

The first conductive pattern 510 may include an outermost first conductive pattern 510X. The outermost first conductive pattern 510X may be disposed between the first encapsulation area R11 of the substrate 100 and the first to third light-emitting devices ED1, ED2, and ED3. An outer sidewall 510c of the outermost first conductive pattern 510X may be toward the first encapsulation area R11 in a plan view. An inner sidewall of the outermost first conductive pattern 510X may be exposed by a corresponding pixel opening 590, and a corresponding one of the first to third light-emitting devices ED1, ED2, and ED3 may be disposed on the inner sidewall of the first conductive pattern 510, e.g., the inner sidewall of outermost first conductive pattern 510X.

The outermost first conductive pattern 510X may include an outermost first lower conductive pattern 511 and an outermost first upper conductive pattern 512. A tip portion 512Z of the outermost first upper conductive pattern 512 may be asymmetrically formed on the outermost first lower conductive pattern 511. In an embodiment, the tip portion 512Z of the outermost first upper conductive pattern 512 may vertically overlap an inner sidewall of the outermost first lower conductive pattern 511 and laterally protrude in a plan view, for example. However, an outer sidewall of the outermost first upper conductive pattern 512 may be vertically aligned with an outer sidewall of the outermost first lower conductive pattern 511.

An upper surface of the outermost first upper conductive pattern 512 may include a first upper surface 512a1 and a second upper surface 512a2 connected to the first upper surface 512a1. At this time, an upper surface of the first upper conductive pattern 512 may correspond to an upper surface of the first conductive pattern 510. The first upper surface 512a1 of the first upper conductive pattern 512 may be a portion adjacent to any one of the first to third light-emitting devices ED1, ED2, and ED3. The second upper surface 512a2 of the outermost first upper conductive pattern 512 may be a portion adjacent to the first encapsulation area R11 of the substrate 100 in a plan view. The second upper surface 512a2 of the outermost first upper conductive pattern 512 may be between the first upper surface 512a1 and the first encapsulation area R11 in a plan view. The second upper surface 512a2 of the outermost first upper conductive pattern 512 may be provided between the first upper surface 512a1 and the outer sidewall 510c of the outermost first conductive pattern 510X in a plan view.

The dummy pattern 600D may be provided on the first upper surface 512a1 of the outermost first upper conductive pattern 512. The dummy pattern 600D may vertically overlap the first upper surface 512a1 of the outermost first upper conductive pattern 512 but may be spaced apart from the second upper surface 512a2 of the outermost first upper conductive pattern 512. An end portion of the dummy pattern 600D may be spaced apart from the first upper conductive pattern 512. Accordingly, a gap area may be provided between the end portion of the dummy pattern 600D and the first upper conductive pattern 512. The end portion of the dummy pattern 600D may include an outer sidewall 600Dc of the dummy pattern 600D.

The outer sidewall 600Dc of the dummy pattern 600D may not be aligned with the outer sidewall 510c of the outermost first conductive pattern 510X. In an embodiment, the outer sidewall 600Dc of the dummy pattern 600D may be offset in a direction from the outer sidewall 510c of the outermost first conductive pattern 510X toward the inner sidewall of the first conductive pattern 510, for example.

The first inorganic pattern 421 may be provided in the edge area of the emission area R10 of the substrate 100 and may fill the gap area between the end portion of the dummy pattern 600D and the first upper conductive pattern 512. The first inorganic pattern 421 may be a gap fill pattern. The first inorganic pattern 421 may be disposed between the dummy intermediate layer 610D and the outermost first upper conductive pattern 512. An outer sidewall of the first inorganic pattern 421 may be vertically aligned with the outer sidewall 600Dc of the dummy pattern 600D. An inner sidewall of the first inorganic pattern 421 is opposite to the outer sidewall of the first inorganic pattern 421 and may be covered by the dummy intermediate layer 610D. The first inorganic pattern 421 may include an inorganic material, such as aluminum oxide, titanium oxide, tantalum oxide, hafnium oxide, zinc oxide, silicon oxide, silicon nitride, silicon oxynitride, ITO, IZO, In₂O₃, IGO, and/or AZO. A thickness T41 of the first inorganic pattern 421 may be about 100 Å to about 3,000 Å. The thickness T41 of the first inorganic pattern 421 satisfies the above range so that the gap area between the first upper conductive pattern 512 and the dummy pattern 600D may be well filled.

The first inorganic encapsulation layer 710 may cover an upper surface of the dummy pattern 600D in the edge area of the emission area R10 of the substrate 100. An outer sidewall of the first inorganic encapsulation layer 710 may be vertically aligned with the outer sidewall 600Dc of the dummy pattern 600D and the outer sidewall of the first inorganic pattern 421. The first inorganic encapsulation layer 710 may be spaced apart from the second upper surface 512a2 of the outermost first upper conductive pattern 512.

The second inorganic encapsulation layer 720 may cover an upper surface and outer sidewall of the first inorganic encapsulation layer 710. The second inorganic encapsulation layer 720 may cover the outer sidewall 600Dc of the dummy pattern 600D, the outer sidewall of the first inorganic pattern 421, and the second upper surface 512a2 of the outermost first upper conductive pattern 512. The second inorganic encapsulation layer 720 may cover the outer sidewall 510c of the outermost first conductive pattern 510X.

Hereinafter, components in the first encapsulation area R11 and the second encapsulation area R12 of the substrate 100 are described.

As shown in FIG. 3B, the buffer layer 111, the gate insulating layer 113, the first inter-insulating film 115, the second inter-insulating film 117, the first organic insulating layer OL1, and the second organic insulating layer OL2 may be provided in the emission area R10 of the substrate 100 as well as the first encapsulation area R11 of the substrate 100. However, the buffer layer 111, the gate insulating layer 113, the first inter-insulating film 115, the second inter-insulating film 117, the first organic insulating layer OL1, and the second organic insulating layer OL2 may be directly adjacent to the second encapsulation area R12 of the substrate 100.

The first conductive pattern 510 and the dummy pattern 600D may be directly adjacent to the first encapsulation area R11 and may be spaced apart from the second encapsulation area R12 of the substrate 100.

The first inorganic insulating layer 310 may extend to the first encapsulation area R11 of the substrate 100 to cover an upper surface of the second organic insulating layer OL2. However, the first inorganic insulating layer 310 may not be provided in the second encapsulation area R12 of the substrate 100. The first inorganic insulating layer 310 may have a third thickness T3. The third thickness T3 of the first inorganic insulating layer 310 may be less than the first thickness T1 of the first inorganic encapsulation layer 710 and the second vertical thickness T2 of the second inorganic encapsulation layer 720. In an embodiment, the third thickness T3 may be about 5,000 Å to about 9,000 Å, for example. The first inorganic insulating layer 310 may include a material different from the materials of the first inorganic encapsulation layer 710, the second inorganic encapsulation layer 720, and the first inorganic pattern 421, but the disclosure is not limited thereto.

The display apparatus 1 may further include the second inorganic pattern 422. The second inorganic pattern 422 may be provided in the second encapsulation area R12 of the substrate 100 to cover an outer sidewall of the first organic insulating layer OL1, an outer sidewall of the second organic insulating layer OL2, and an outer sidewall of the first inorganic insulating layer 310. The second inorganic pattern 422 may further cover an outer sidewall of the stacked structure 110. The second inorganic pattern 422 may be formed by a single process with the first inorganic pattern 421. In an embodiment, the second inorganic pattern 422 may include the same material as that of the first inorganic pattern 421, for example. However, a thickness T4 of the second inorganic pattern 422 may be less than the thickness T41 of the first inorganic pattern 421. In an embodiment, the thickness T4 of the second inorganic pattern 422 may be about 20% to about 40% of the thickness T41 of the first inorganic pattern 421, for example. The thickness T4 of the second inorganic pattern 422 may be less than the first thickness T1 of the first inorganic encapsulation layer 710, the second vertical thickness T2 of the second inorganic encapsulation layer 720, and the third thickness T3 of the first inorganic insulating layer 310.

The second inorganic pattern 422 may be spaced apart from the emission area R10 and may be directly adjacent to the first encapsulation area R11 of the substrate 100. Accordingly, the second inorganic pattern 422 may not extend onto an upper surface of the first inorganic insulating layer 310 in the first encapsulation area R11 of the substrate 100. The second inorganic pattern 422 may expose at least a portion of an upper surface of the substrate 100 in the second encapsulation area R12.

The second inorganic encapsulation layer 720 may be provided in the emission area R10 of the substrate 100 as well as the first encapsulation area R11 and the second encapsulation area R12. The second inorganic encapsulation layer 720 may cover the upper surface of the first inorganic insulating layer 310 in the first encapsulation area R11 of the substrate 100. The second inorganic encapsulation layer 720 may cover the upper surface of the substrate 100 in the second encapsulation area R12. The second inorganic encapsulation layer 720 may be disposed on the outer sidewall of the stacked structure 110, the outer sidewall of the first organic insulating layer OL1, the outer sidewall of the second organic insulating layer OL2, and the outer sidewall of the first inorganic insulating layer 310 to cover the second inorganic pattern 422. The second inorganic pattern 422 may be between the second inorganic encapsulation layer 720 and the outer sidewalls of the first and second organic insulating layers OL1 and OL2. The second inorganic encapsulation layer 720 may have a second horizontal thickness T22 from the outer sidewall of the second inorganic pattern 422. The second horizontal thickness T22 of the second inorganic encapsulation layer 720 may be less than the second vertical thickness T2 of the second inorganic encapsulation layer 720. In an embodiment, the second horizontal thickness T22 may be about 20% to about 40% of the second vertical thickness T2, for example. The second horizontal thickness T22 of the second inorganic encapsulation layer 720 may be less than the first thickness T1 of the first inorganic encapsulation layer 710, and may be greater than the thickness T4 of the second inorganic pattern 422.

The first inorganic encapsulation layer 710 may be spaced apart from the first encapsulation area R11 and the second encapsulation area R12 of the substrate 100. Accordingly, a thickness of the encapsulation layer 700 in the emission area R10 of the substrate 100 may be greater than a thickness of the encapsulation layer 700 in the first encapsulation area R11 of the substrate 100. The thickness of the encapsulation layer 700 in the emission area R10 of the substrate 100 may be a sum of the first thickness T1 of the first inorganic encapsulation layer 710 and the second vertical thickness T2 of the second inorganic encapsulation layer 720. A thickness of the encapsulation layer 700 in the first encapsulation area R11 of the substrate 100 may be the second vertical thickness T2. A thickness of the encapsulation layer 700 in the emission area R10 of the substrate 100 may be greater than a sum of the second vertical thickness T2 of the second inorganic encapsulation layer 720 and the third thickness T3 of the first inorganic insulating layer 310 in the first encapsulation area R11 of the substrate 100. A sum of the thickness T4 of the second inorganic pattern 422 and the second horizontal thickness T22 of the second inorganic encapsulation layer 720 may be less than the thickness of the encapsulation layer 700 in the emission area R10 of the substrate 100, and may be less than a sum of the second vertical thickness T2 of the second inorganic encapsulation layer 720 and the third thickness T3 of the first inorganic insulating layer 310 in the first encapsulation area R11 of the substrate 100.

Hereinafter, components in the connection area R2 of the substrate 100 are described with reference to FIG. 3D together with FIGS. 3A to 3C.

Referring to FIG. 3D, the connection area R2 of the substrate 100 may be connected to the emission area R10 of the substrate 100 through the first encapsulation area R11 of the substrate 100. The first encapsulation area R11 of the substrate 100 may be disposed between the connection area R2 and the emission area R10 of the substrate 100.

The first organic insulating layer OL1 and the second organic insulating layer OL2 may be arranged in the emission area R10 and the first encapsulation area R11 as well as the connection area R2 of the substrate 100. The stacked structure 110 may be spaced apart from the connection area R2 of the substrate 100. That is, the stacked structure 110 may not be provided in the connection area R2 of the substrate 100. Rather, the display apparatus 1 may further include a lower organic insulating layer OL3. The lower organic insulating layer OL3 may be disposed between the substrate 100 and the first organic insulating layer OL1. An upper surface of the lower organic insulating layer OL3 may be provided at the same vertical level as or similar vertical level to that of an upper surface of the second inter-insulating film 117. Accordingly, the first organic insulating layer OL1 in the emission area R10 of the substrate 100 may be well connected to the first organic insulating layer OL1 in the connection area R2 of the substrate 100 through the first encapsulation area R11. The lower organic insulating layer OL3 may include acrylic resin, BCB, polyimide, or HMDSO. The lower organic insulating layer OL3 may not be provided in the emission area R10, the first encapsulation area R11 and the second encapsulation area R12 of the substrate 100.

A layer/film including an inorganic material may have relatively low elongation characteristics. By embodiments, the stacked structure 110 including an inorganic material is not provided in the connection area R2 of the substrate 100, and thus the display apparatus 1 may show improved stretchable characteristics in the connection area R2 of the substrate 100.

The line pattern 200 may be disposed between the first organic insulating layer OL1 and the second organic insulating layer OL2 in the connection area R2 of the substrate 100. The line pattern 200 in the connection area R2 of the substrate 100 may be connected to the line pattern 200 (refer to FIG. 3B) in the emission area R10 of the substrate 100.

The second conductive patterns 520 may be provided in the connection area R2 of the substrate 100, as described above with reference to FIG. 3A. The second conductive patterns 520 may be disposed on the second organic insulating layer OL2. The second conductive patterns 520 may be spaced apart from each other. When a single layer in which the second conductive patterns 520 are connected to each other is formed, the connection area R2 of the substrate 100 may have relatively low stretchable characteristics. By embodiments, because the second conductive patterns 520 are spaced apart from the first conductive pattern 510, and the second conductive patterns 520 are spaced apart from each other, an area in which the second conductive patterns 520 are not provided may be formed in the connection area R2 of the substrate 100. Accordingly, the display apparatus 1 may show improved stretchable characteristics in the connection area R2 of the substrate 100. The display apparatus 1 may have improved stretchable, flexible, rollable, and bendable characteristics.

The second conductive patterns 520 may be electrically connected to the line pattern 200 by through holes TH. The through holes TH may penetrate the second organic insulating layer OL2. Even when the second conductive patterns 520 are physically spaced apart from each other, the second conductive patterns 520 may be electrically connected to each other through the line pattern 200.

Each of the second conductive patterns 520 may include a second lower conductive pattern 521 and a second upper conductive pattern 522. The second lower conductive pattern 521 may be provided on the second organic insulating layer OL2, and may extend into a corresponding through hole TH to contact the line pattern 200. The second lower conductive pattern 521 may be formed in a single process with the first lower conductive pattern 511 of FIG. 3B. The second lower conductive pattern 521 may include the same material as that of the first lower conductive pattern 511, and may have substantially the same thickness.

The second upper conductive pattern 522 may be provided on the second lower conductive pattern 521 and cover an upper surface of the second lower conductive pattern 521. The second upper conductive pattern 522 may be formed in a single process with the first upper conductive pattern 512 of FIG. 3B. The second upper conductive pattern 522 may include the same material as that of the first upper conductive pattern 512, and may have substantially the same thickness. Unlike the first upper conductive pattern 512, the second upper conductive pattern 522 may not have a tip portion. In an embodiment, a sidewall of the second upper conductive pattern 522 may be aligned with a sidewall of the second lower conductive pattern 521, for example.

Second inorganic insulating layers 320 may be provided in the connection area R2 of the substrate 100. The second inorganic insulating layers 320 may be provided between the second organic insulating layer OL2 and the second conductive patterns 520. Some of the second inorganic insulating layers 320 may be further provided between the line pattern 200 and the second conductive patterns 520. However, the second inorganic insulating layers 320 may expose at least a portion of upper surfaces of the line pattern 200 in the through holes TH. The second inorganic insulating layers 320 may be spaced apart from each other so that an area in which the second inorganic insulating layers 320 are not provided may be formed in the connection area R2 of the substrate 100. Accordingly, the display apparatus 1 may show improved stretchable characteristics in the connection area R2 of the substrate 100.

The second inorganic insulating layers 320 may be spaced apart from the island area R1 of the substrate 100. In an embodiment, the second inorganic insulating layers 320 may be spaced apart from the first inorganic insulating layer 310, for example. Because the second inorganic insulating layers 320 are spaced apart from the first inorganic insulating layer 310, the display apparatus 1 may show improved stretchable characteristics in the connection area R2 of the substrate 100. The second inorganic insulating layers 320 may be formed in a single process with the first inorganic insulating layer 310. The second inorganic insulating layers 320 may include the same material as that of the first inorganic insulating layer 310. In an embodiment, a thickness of each of the second inorganic insulating layers 320 may be substantially the same as the third thickness T3 of the first inorganic insulating layer 310, for example.

The display apparatus 1 may further include a lower protective pattern. The lower protective pattern may include a first lower protective pattern 431 and second lower protective patterns 432. The first lower protective pattern 431 may be disposed between the second organic insulating layer OL2 and the first inorganic insulating layer 310 in the first encapsulation area R11 of the substrate 100. The first lower protective pattern 431 may be disposed below the outer sidewall of the outermost first conductive pattern 510X. The first lower protective pattern 431 may include a transparent conductive oxide such as IZO, IGZO, ITO, ZnO, In₂O₃, IGO, or AZO.

The second lower protective patterns 432 may be provided in the connection area R2 of the substrate 100 and may be spaced apart from the first lower protective pattern 431. The second lower protective patterns 432 may be arranged between the second organic insulating layer OL2 and the second inorganic insulating layer 320. The second lower protective patterns 432 may be arranged to be spaced apart from lower surfaces of the second upper conductive pattern 522, and may be disposed below outer sidewalls of the second upper conductive pattern 522. The second lower protective patterns 432 may be formed in a single process with the first lower protective pattern 431. The second lower protective patterns 432 may include the same material as that of the first lower protective pattern 431, and may have substantially the same thickness.

The display apparatus 1 may further include a first gap fill pattern 441 and second gap fill patterns 442. The first gap fill pattern 441 may be disposed between the second organic insulating layer OL2 and the first inorganic insulating layer 310 in the first encapsulation area R11 of the substrate 100. The first gap fill pattern 441 may be provided on an outer sidewall of the first lower protective pattern 431.

The second gap fill patterns 442 may be arranged between the second organic insulating layer OL2 and the second inorganic insulating layer 320 in the connection area R2 of the substrate 100. The second gap fill patterns 442 may be spaced apart from the first gap fill pattern 441. The second gap fill patterns 442 may be spaced apart from each other. The second gap fill patterns 442 may be provided on outer sidewalls of the second lower protective patterns 432.

The first gap fill pattern 441 and the second gap fill patterns 442 may include a transparent conductive oxide such as IZO, IGZO, ITO, ZnO, In₂O₃, IGO, or AZO.

The first inorganic encapsulation layer 710 may be disposed to be spaced apart from the connection area R2 of the substrate 100. Because the first inorganic encapsulation layer 710 having the first thickness T1, which is relatively large, is not provided in the connection area R2 of the substrate 100, the display apparatus 1 may have improved stretchable, flexible, rollable, and bendable characteristics in the connection area R2 of the substrate 100.

The dummy pattern 600D may not be provided in the connection area R2 of the substrate 100 and may be spaced apart from the connection area R2 of the substrate 100.

The second inorganic encapsulation layer 720 may be disposed in the connection area R2 of the substrate 100 to cover upper surfaces and sidewalls of the second conductive patterns 520. Because the dummy pattern 600D and the first inorganic encapsulation layer 710 are not provided on the second conductive patterns 520, the second inorganic encapsulation layer 720 may contact the second conductive patterns 520. The second inorganic encapsulation layer 720 may seal the second conductive patterns 520 to protect the second conductive patterns 520 from external impurities. The second inorganic encapsulation layer 720 may further cover an upper surface of the second organic insulating layer OL2 and the second inorganic insulating layers 320. Because the first inorganic encapsulation layer 710 is not provided in the connection area R2 of the substrate 100, the second inorganic encapsulation layer 720 may be in physical contact with the second organic insulating layer OL2 and the second inorganic insulating layers 320. The second inorganic encapsulation layer 720 may further cover a sidewall of the first gap fill pattern 441 and sidewalls of the second gap fill patterns 442.

The second inorganic encapsulation layer 720 may have the second vertical thickness T2 as described above in the emission area R10 of the substrate 100. The second vertical thickness T2 may be less than the first thickness T1 of the first inorganic encapsulation layer 710. Because the second inorganic encapsulation layer 720 having the second vertical thickness T2 covers the second conductive patterns 520, the second conductive patterns 520 may be protected while the stretchable characteristics of the connection area R2 of the substrate 100 are not greatly restricted.

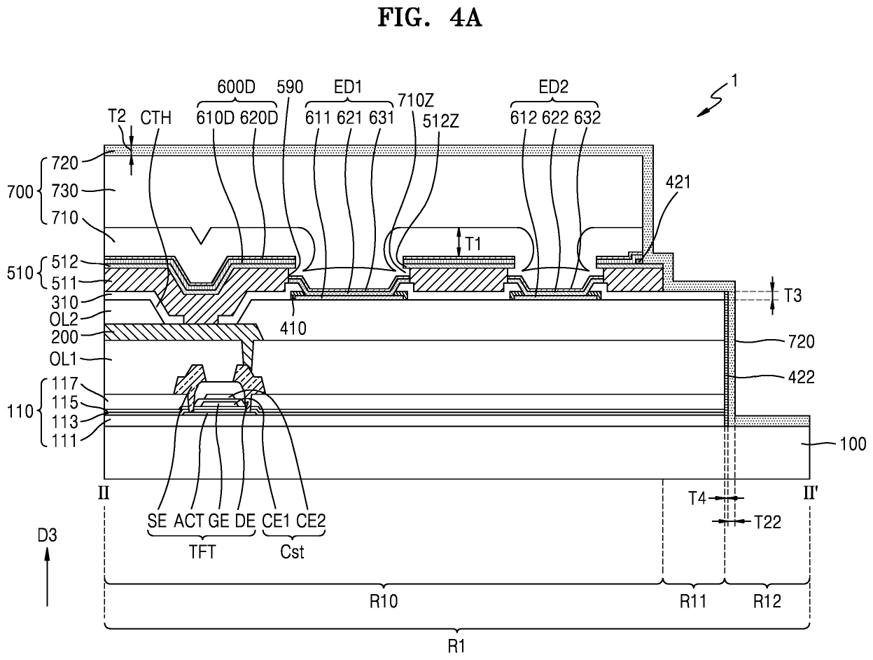

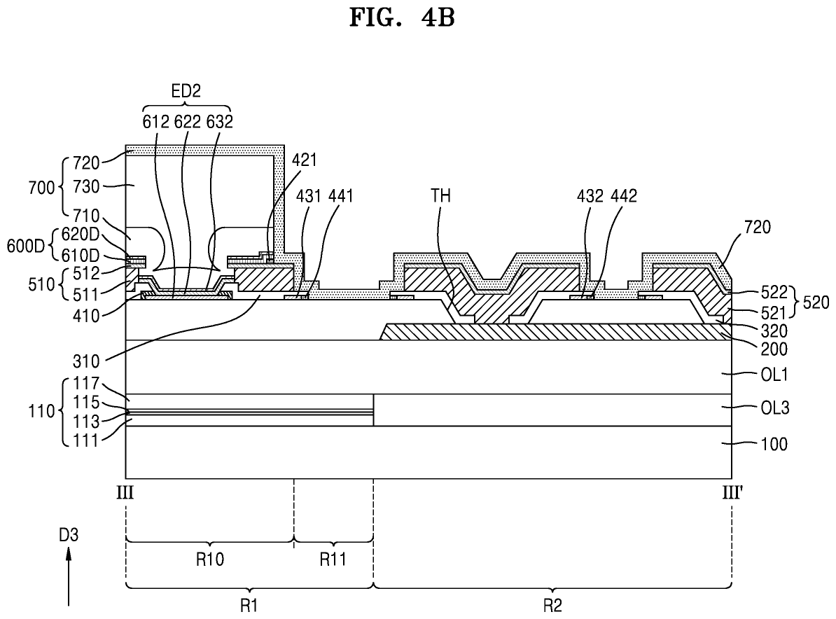

FIGS. 4A and 4B are diagrams for explaining display apparatuses according to different embodiments. FIG. 4A corresponds to a cross-sectional view of the display apparatus taken along line II-II′ of FIG. 3A, and FIG. 4B corresponds to a cross-sectional view of the display apparatus taken along line III-III′ of FIG. 3A. Hereinafter, descriptions already given above are omitted.

Referring to FIGS. 4A and 4B, a display apparatus 1 may include the substrate 100, the first and second light-emitting devices ED1 and ED2, the first organic insulating layer OL1, the second organic insulating layer OL2, the line pattern 200, the first and second conductive patterns 510 and 520, the first inorganic insulating layer 310, the second inorganic insulating layer 320, the first inorganic pattern 421, the second inorganic pattern 422, and the encapsulation layer 700.

The encapsulation layer 700 may include the first inorganic encapsulation layer 710, the second inorganic encapsulation layer 720, and an organic encapsulation layer 730. The organic encapsulation layer 730 may be provided in the emission area R10 of the substrate 100, and may be disposed between the first inorganic encapsulation layer 710 and the second inorganic encapsulation layer 720. The organic encapsulation layer 730 may be spaced apart from the first and second encapsulation areas R11 and R12 and the connection area R2 of the substrate 100. A thickness of the organic encapsulation layer 730 may be greater than the first thickness T1 of the first inorganic encapsulation layer 710 and the second vertical thickness T2 of the second inorganic encapsulation layer 720. The organic encapsulation layer 730 may include a polymer such as an acrylic resin, an epoxy resin, polyimide, and/or polyethylene.

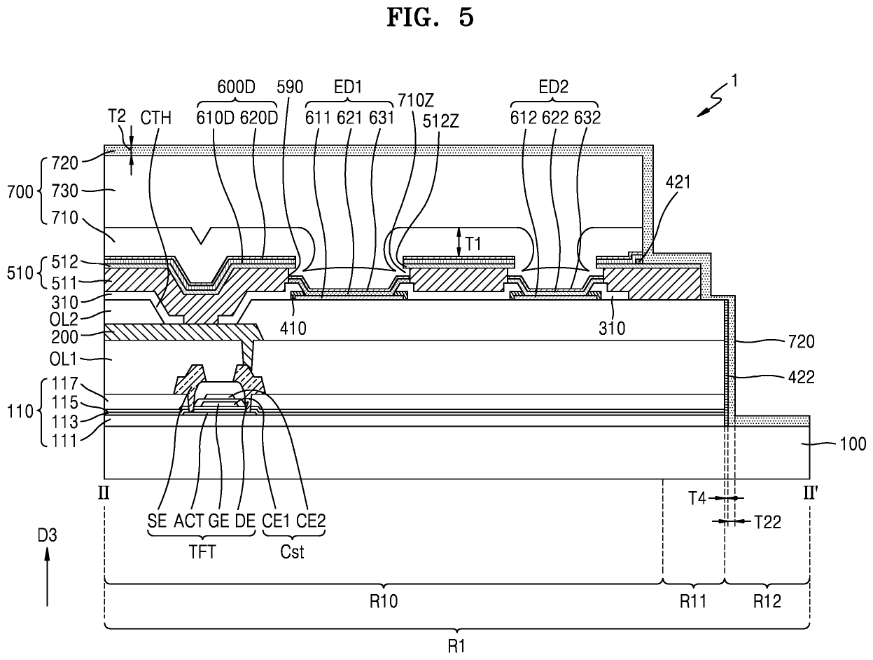

FIG. 5 is a diagram for explaining another embodiment of a display apparatus, and corresponds to a cross-sectional view of the display apparatus taken along line II-II′ of FIG. 3A.

Referring to FIG. 5, a display apparatus 1 may include the substrate 100, the first and second light-emitting devices ED1 and ED2, the first organic insulating layer OL1, the second organic insulating layer OL2, the line pattern 200, the first conductive pattern 510, the first inorganic insulating layer 310, the first inorganic pattern 421, the second inorganic pattern 422, and the encapsulation layer 700. The display apparatus 1 may further include the second inorganic insulating layer 320 and the second conductive patterns 520 of FIG. 3D.

The first inorganic insulating layer 310 may cover the second organic insulating layer OL2 in the emission area R10 of the substrate 100. Unlike FIG. 4A, the first inorganic insulating layer 310 may be spaced apart from the first encapsulation area R11 of the substrate 100 to expose an upper surface of the second organic insulating layer OL2 in the first encapsulation area R11 of the substrate 100.

The first conductive pattern 510 may extend to the first encapsulation area R11 of the substrate 100 to cover the exposed upper surface of the second organic insulating layer OL2. The first conductive pattern 510 may be in direct contact with the upper surface of the second organic insulating layer OL2.

The second inorganic encapsulation layer 720 may cover the first conductive pattern 510 in the first encapsulation area R11 of the substrate 100. The second inorganic encapsulation layer 720 may be spaced apart from the first inorganic insulating layer 310 in the first encapsulation area R11 of the substrate 100.

By embodiments, because the first conductive pattern 510 further extends to the first encapsulation area R11 of the substrate 100, a space for forming the first conductive pattern 510 may be sufficiently secured in the island area R1 of the substrate 100.

The encapsulation layer 700 may include the first inorganic encapsulation layer 710, the second inorganic encapsulation layer 720, and the organic encapsulation layer 730. Unlike shown in FIG. 5, the encapsulation layer 700 may not include the organic encapsulation layer 730.

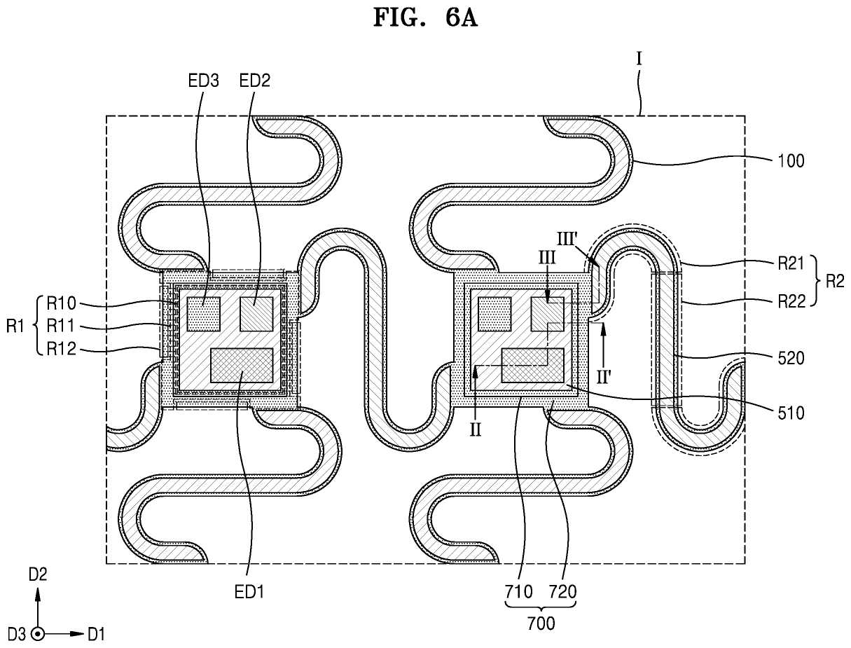

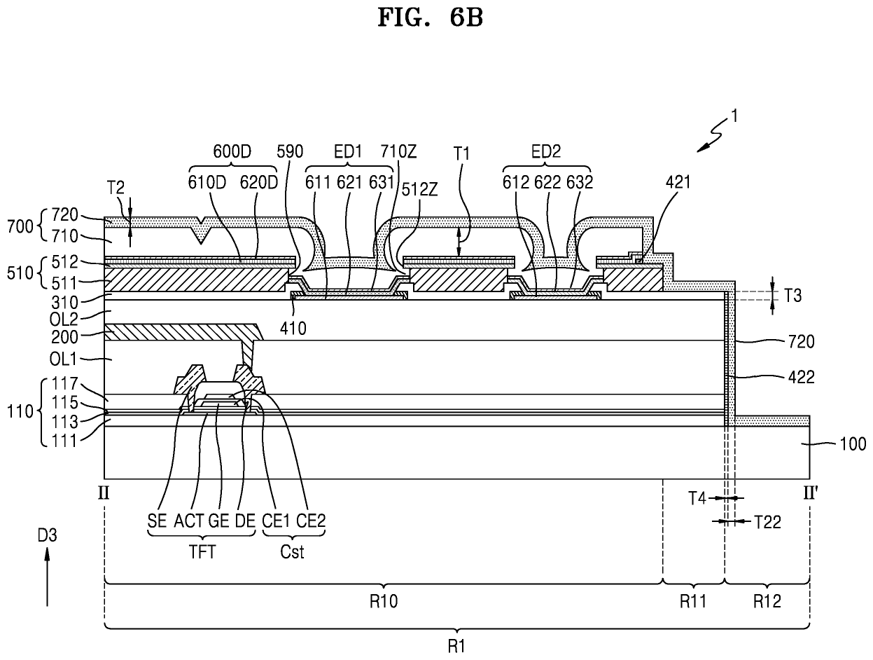

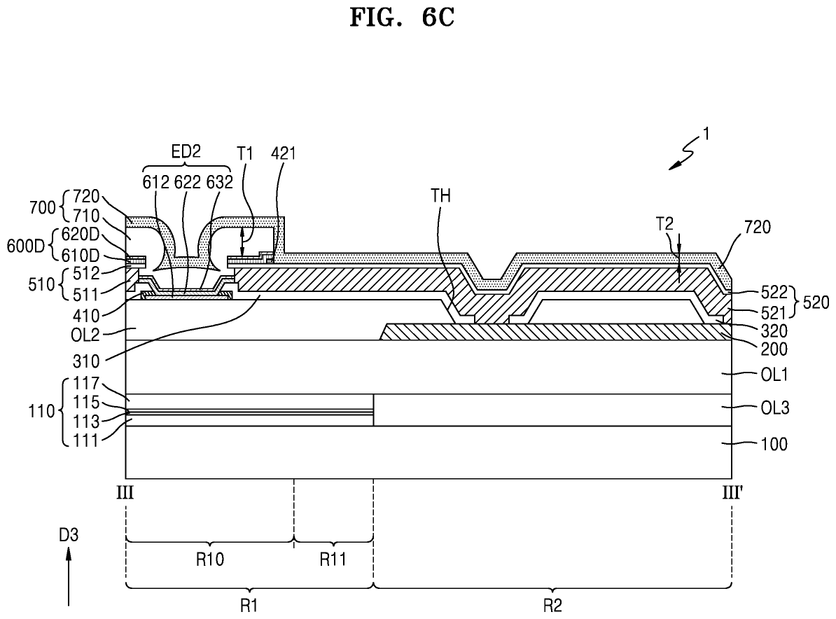

FIG. 6A is an enlarged plan view of another embodiment of a portion of a display area of a display apparatus, and corresponds to an enlarged diagram of a region I of FIG. 1. FIG. 6B is a cross-sectional view of the display apparatus taken along line II-II′ of FIG. 6A. FIG. 6C is a cross-sectional view of the display apparatus taken along line III-III′ of FIG. 6A.

Referring to FIGS. 6A, 6B, and 6C, the display apparatus 1 may include the substrate 100, the first to third light-emitting devices ED1, ED2, and ED3, the first organic insulating layer OL1, the second organic insulating layer OL2, the line pattern 200, the first and second conductive patterns 510 and 520, the first inorganic insulating layer 310, the second inorganic insulating layer 320, the first inorganic pattern 421, the second inorganic pattern 422, and the encapsulation layer 700.

Unlike the above description, a single second conductive pattern 520 may be provided in the connection area R2 of the substrate 100. The second conductive pattern 520 may extend along the connection area R2 of the substrate 100. The first conductive pattern 510 may extend onto the second organic insulating layer OL2 in the first encapsulation area R11 of the substrate 100, as shown in FIG. 6C. The first conductive pattern 510 may be connected to the second conductive pattern 520 without a boundary, and may be unitary with the second conductive pattern 520. In an embodiment, the second lower conductive pattern 521 may be connected to the first lower conductive pattern 511 without a boundary, and may be unitary with the first lower conductive pattern 511, for example. The second upper conductive pattern 522 may be connected to the first upper conductive pattern 512 without a boundary, and may be unitary with the first upper conductive pattern 512.

By embodiments, the contact hole CTH (refer to FIGS. 3A and 3B) may not be defined in the emission area R10 of the substrate 100. The first conductive pattern 510 may be spaced apart from the line pattern 200 in the emission area R10 of the substrate 100. The first conductive pattern 510 may be electrically connected to the line pattern 200 through the second conductive pattern 520 in the connection area R2 of the substrate 100. Unlike the above description, the contact hole CTH described with reference to FIGS. 3A and 3B may be defined in the second organic insulating layer OL2 in the emission area R10 of the substrate 100, and the first conductive pattern 510 may extend into the contact hole CTH to be connected to the line pattern 200.

The first inorganic insulating layer 310 and the second inorganic insulating layer 320 may be unitary. In an embodiment, the first inorganic insulating layer 310 may further extend to the first encapsulation area R11 of the substrate 100, as shown in FIG. 6C, for example. The first inorganic insulating layer 310 may be connected to the second inorganic insulating layer 320 without a boundary.

The display apparatus 1 may not include the first lower protective pattern 431, the second lower protective patterns 432, the first gap fill pattern 441 and the second gap fill patterns 442 as described with reference to FIG. 3D.

The encapsulation layer 700 may include the first inorganic encapsulation layer 710 and the second inorganic encapsulation layer 720. The encapsulation layer 700 may further include the organic encapsulation layer 730 as described with reference to FIGS. 4A and 4B.

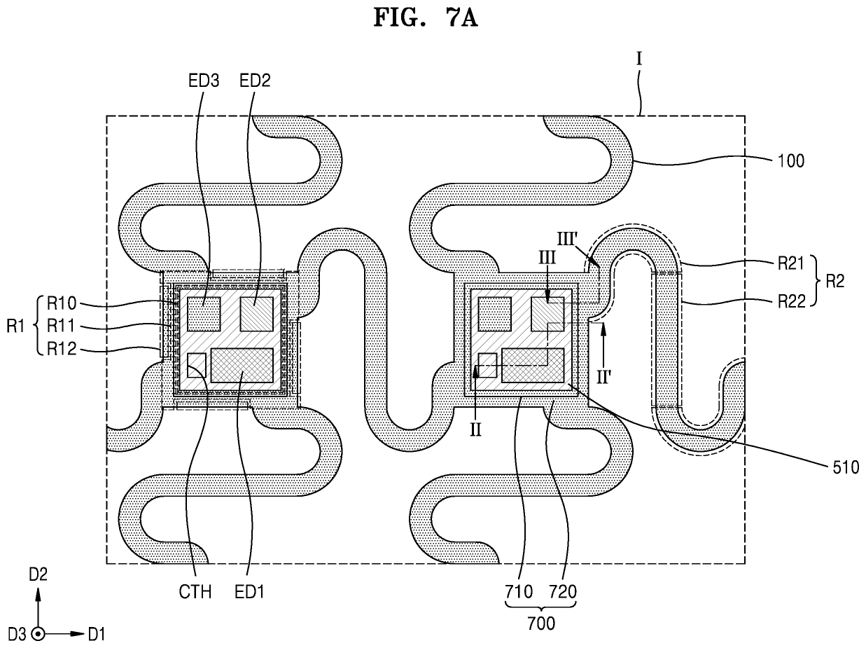

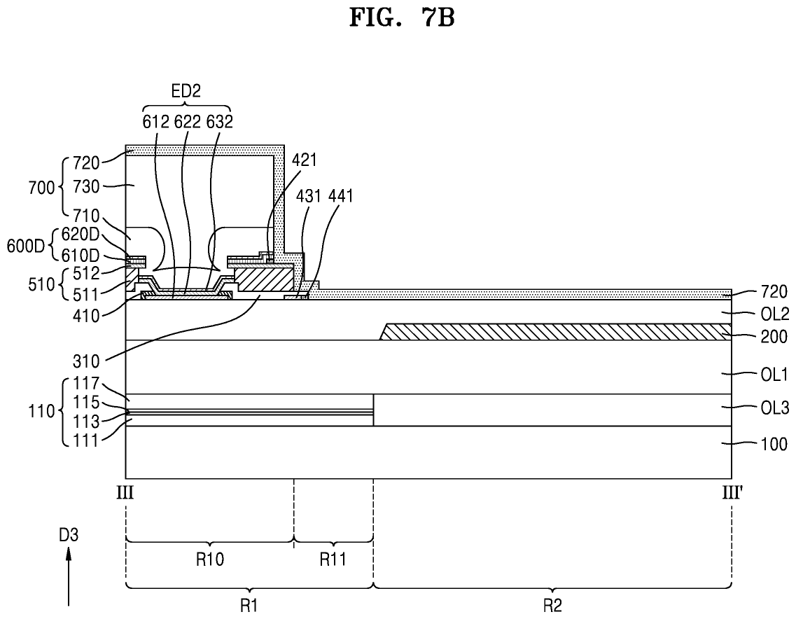

FIG. 7A is an enlarged plan view of another embodiment of a portion of a display area of a display apparatus, and corresponds to an enlarged diagram of the region I of FIG. 1. FIG. 7B is a cross-sectional view of the display apparatus taken along line III-III′ of FIG. 7A.

Referring to FIGS. 7A and 7B, the display apparatus 1 may include the substrate 100, the first to third light-emitting devices ED1, ED2, and ED3, the first organic insulating layer OL1, the second organic insulating layer OL2, the line pattern 200, the first conductive pattern 510, the first inorganic insulating layer 310, the first inorganic pattern 421, the second inorganic pattern 422, and the encapsulation layer 700.

The display apparatus 1 may not include the second conductive patterns 520, the second inorganic insulating layer 320, the second lower protective patterns 432, and the second gap fill patterns 442, unlike shown in FIGS. 3A to 3D. Accordingly, the second inorganic encapsulation layer 720 may cover the second organic insulating layer OL2 in the first encapsulation area R11 and the connection area R2 of the substrate 100. In an embodiment, the second inorganic encapsulation layer 720 may contact an upper surface of the second organic insulating layer OL2 in the first encapsulation area R11 and the connection area R2 of the substrate 100, for example.

Components in the emission area R10 of the substrate 100 may be substantially the same as the examples described above with reference to FIGS. 3A to 3C, 4A, or 5. The encapsulation layer 700 may include the first inorganic encapsulation layer 710, the second inorganic encapsulation layer 720, and the organic encapsulation layer 730. Unlike shown in FIG. 7B, the encapsulation layer 700 may not include the organic encapsulation layer 730.

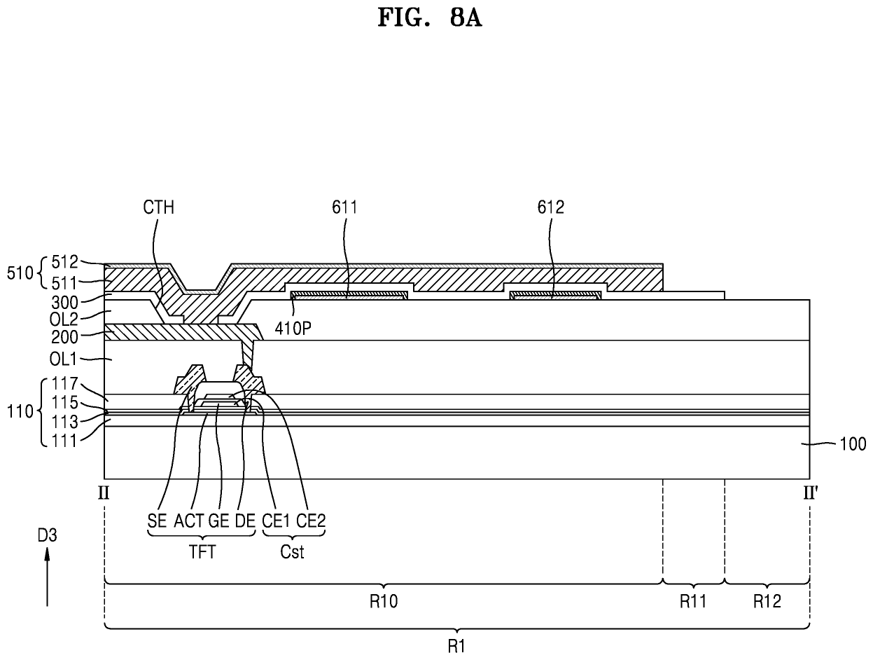

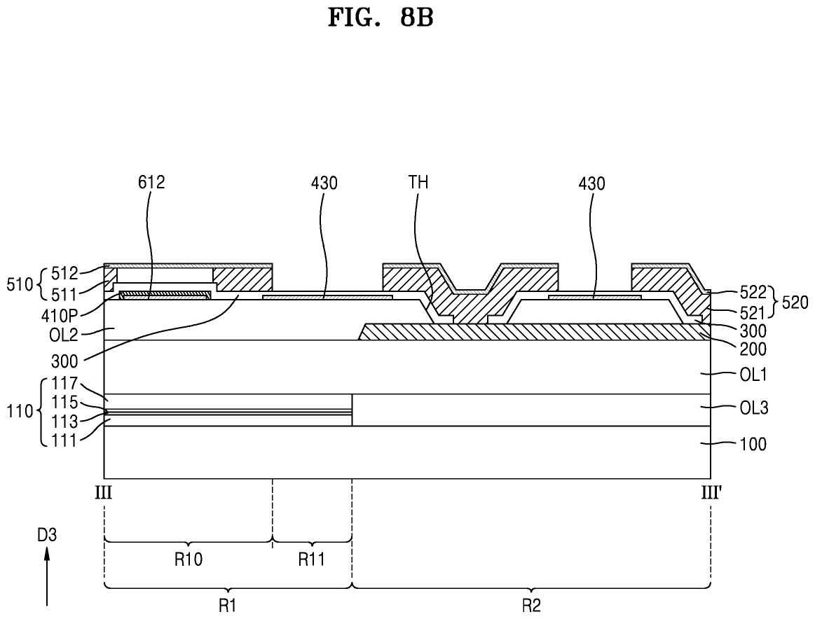

FIGS. 8A to 14B are diagrams for explaining an embodiment of a method of manufacturing a display apparatus. FIGS. 8A, 9A, 10A, 11A, 12A, 13A, and 14A each corresponds to a cross-sectional view taken along line II-II′ of FIG. 3A, and FIGS. 8B, 9B, 10B, 11B, 12B, 13B, and 14B each corresponds to a cross-sectional view taken along line III-III′ of FIG. 3A.

Referring to FIGS. 8A and 8B, the stacked structure 110 may be formed in the emission area R10 and the first and second encapsulation areas R11 and R12 of the substrate 100. The thin-film transistor TFT and the storage capacitor Cst may be formed in the emission area R10 of the substrate 100. The lower organic insulating layer OL3 may be formed in the connection area R2 of the substrate 100. The first organic insulating layer OL1 and the second organic insulating layer OL2 may be formed on the stacked structure 110 and the lower organic insulating layer OL3. The line pattern 200 may be formed on the first organic insulating layer OL1. The contact hole CTH and the through hole TH may be defined in the second organic insulating layer OL2 to expose an upper surface of the line pattern 200. The contact hole CTH may be defined in the emission area R10 of the substrate 100, and the through hole TH may be defined in the connection area R2 of the substrate 100.

The first and second lower electrodes 611 and 612 may be formed on an upper surface of the second organic insulating layer OL2. An electrode protective layer 410P may be formed on the first and second lower electrodes 611 and 612 to cover the first and second lower electrodes 611 and 612. As shown in FIG. 8B, lower protective layers 430 may be formed in the first encapsulation area R11 and the connection area R2 of the substrate 100 to cover the second organic insulating layer OL2. Herein, the first encapsulation area R11 in which the lower protective layers 430 are formed may be an area disposed between the emission area R10 and the connection area R2. A lower protective layer 430 may be formed in a single process with the electrode protective layer 410P, or may be formed in a separate process.

An inorganic insulating layer 300 may be formed in the emission area R10, the first and second encapsulation areas R11 and R12, and the connection area R2 of the substrate 100 to cover the second organic insulating layer OL2, the electrode protective layer 410P, and the lower protective layers 430. The inorganic insulating layer 300 may extend onto inner sidewalls of the contact hole CTH and the through hole TH and expose the upper surface of the line pattern 200.

The first conductive pattern 510 may be formed in the emission area R10 of the substrate 100, and the second conductive patterns 520 may be formed in the connection area R2 of the substrate 100. The first conductive pattern 510 and the second conductive patterns 520 may cover the inorganic insulating layer 300. The first conductive pattern 510 may extend into the contact hole CTH to be connected to the line pattern 200. The second conductive patterns 520 may extend into the through hole TH to be connected to the line pattern 200. By embodiments, a lower metal layer and an upper metal layer may be sequentially formed on the inorganic insulating layer 300. In particular, the lower metal layer and the upper metal layer may be formed in the emission area R10, the first and second encapsulation areas R11 and R12, and the connection area R2 of the substrate 100. The lower metal layer and the upper metal layer may be etched by a first photoresist pattern (not shown). The first photoresist pattern (not shown) may be formed by a photolithography process. The lower metal layer may be etched to form the first lower conductive pattern 511 and the second lower conductive pattern 521, which are spaced apart from each other. The upper metal layer may be etched to form the first upper conductive pattern 512 and the second upper conductive pattern 522, which are spaced apart from each other. Accordingly, the first conductive pattern 510 and the second conductive patterns 520 may be formed. The first conductive pattern 510 and the second conductive patterns 520 may be substantially the same as the examples described above with reference to FIGS. 3A to 3D or 4A to 4B. The first conductive pattern 510 may expose the inorganic insulating layer 300 in the first encapsulation area R11 of the substrate 100 and expose the second organic insulating layer OL2 in the second encapsulation area R12. The second conductive patterns 520 may expose the inorganic insulating layer 300 in the connection area R2 of the substrate 100.

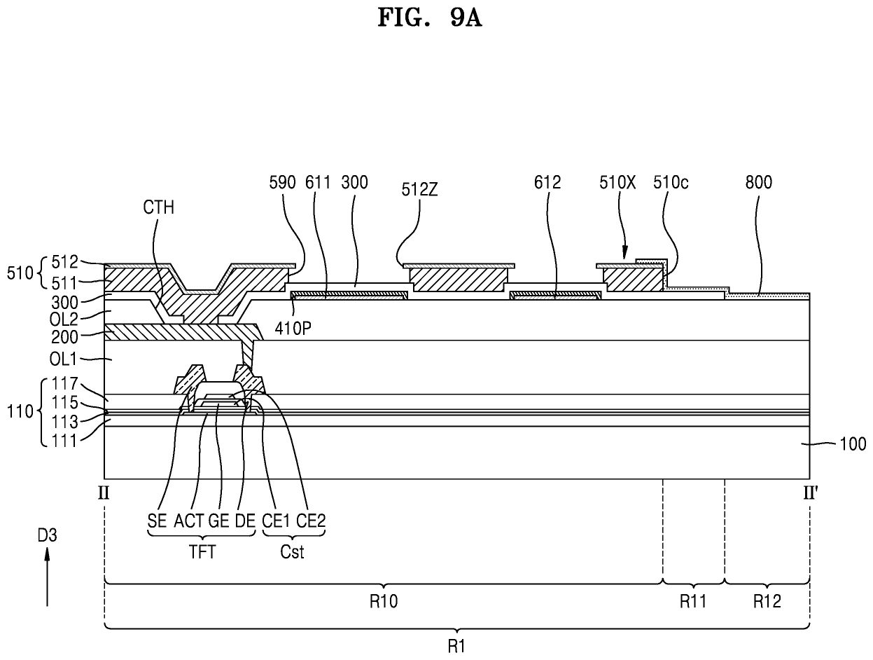

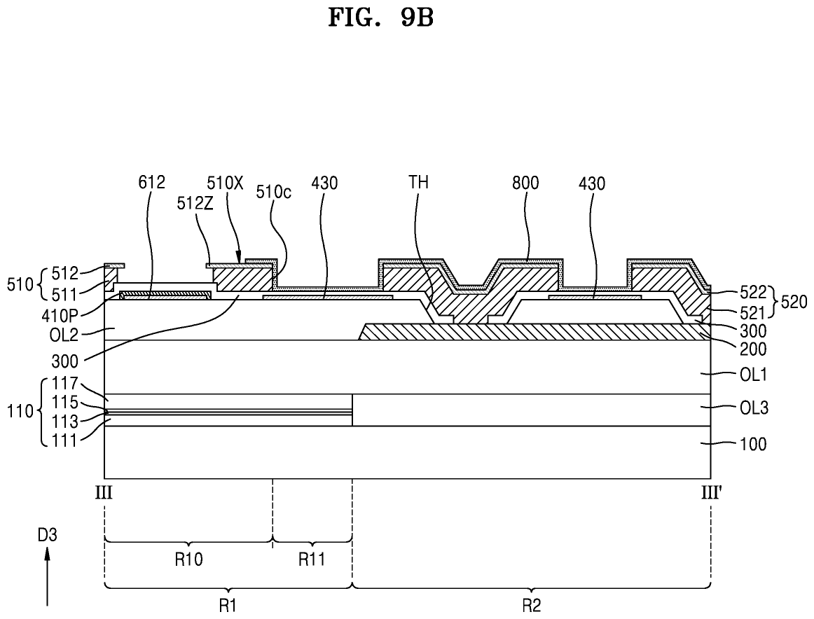

Referring to FIGS. 9A and 9B, an etch stop film 800 may be formed in the emission area R10, the first and second encapsulation areas R11 and R12, and the connection area R2 of the substrate 100. The etch stop film 800 may cover the inorganic insulating layer 300 exposed in the first encapsulation area R11 of the substrate 100, and may cover the second organic insulating layer OL2 exposed in the second encapsulation area R12. The etch stop film 800 may extend to the emission area R10 of the substrate 100 to cover a portion of an upper surface (e.g., the second upper surface 512a2 of FIG. 3C) and the outer sidewall 510c of the outermost first conductive pattern 510X. The etch stop film 800 may cover the second conductive patterns 520 and the inorganic insulating layer 300 in the connection area R2 of the substrate 100.

The first conductive pattern 510 may be patterned by an etching process so that the pixel openings 590 may be defined in the first conductive pattern 510. The etching process may be performed by a second photoresist pattern (not shown). The second photoresist pattern may be formed by a photolithography process. The etching of the first conductive pattern 510 may include an etching process of the first lower conductive pattern 511 and an etching process of the first upper conductive pattern 512. The etching process of the first upper conductive pattern 512 may include a dry etching process, and the etching process of the first lower conductive pattern 511 may include a wet etching process, but the disclosure is not limited thereto. The pixel openings 590 may expose the inorganic insulating layer 300. A sidewall of the first lower conductive pattern 511, which is exposed by the pixel openings 590, may be further etched to form an undercut on the sidewall of the first lower conductive pattern 511. Accordingly, tip portions 512Z of the first upper conductive pattern 512 may be formed.

The second conductive patterns 520 may not be exposed to the etching processes by the second photoresist pattern.

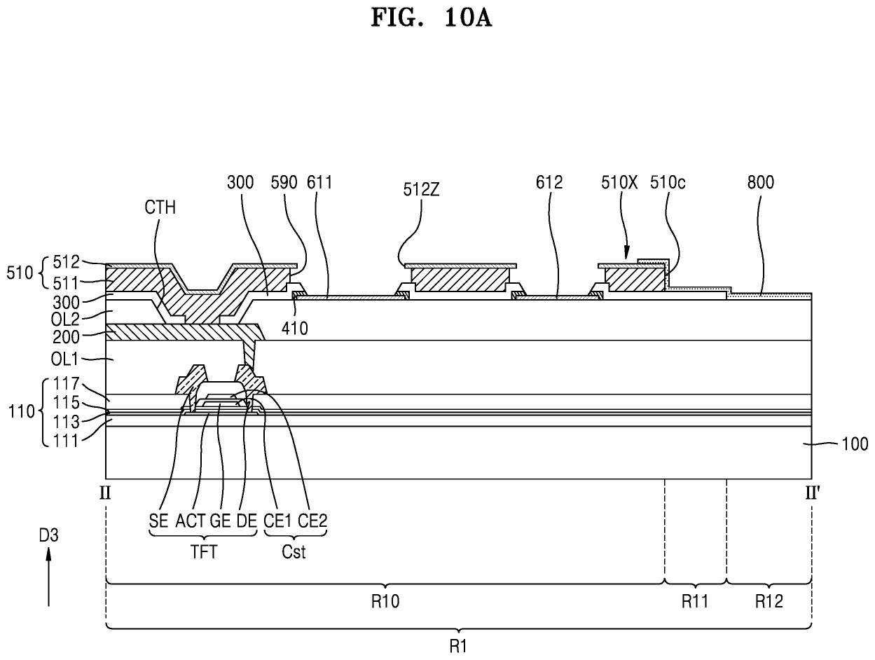

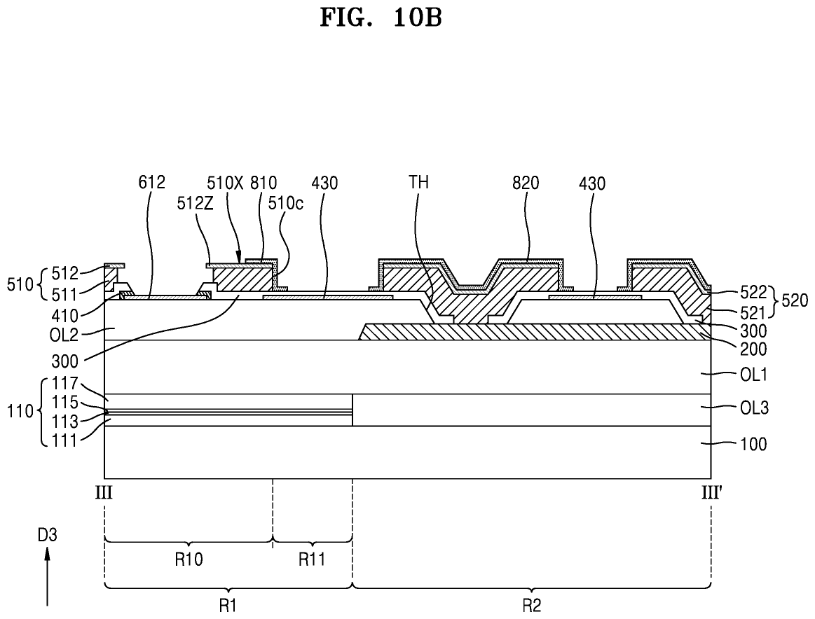

Referring to FIGS. 10A and 10B, a first etching process may be performed on the inorganic insulating layer 300. Portions of the inorganic insulating layer 300, which are exposed by the pixel openings 590, may be removed by the first etching process to expose the electrode protective layer 410P. The first etching process may be a dry etching process, but is not limited thereto.

A second etching process may be performed on the electrode protective layer 410P to form the electrode protective patterns 410. In an embodiment, the electrode protective layer 410P exposed by the pixel openings 590 may be partially removed by the second etching process, and the first and second lower electrodes 611 and 612 may be exposed, for example. As a result of the second etching process, the electrode protective patterns 410 described with reference to FIG. 3B may be formed from the electrode protective layer 410P in the emission area R10 of the substrate 100. The second etching process may be a dry etching process.

A third etching process may be performed on the etch stop film 800 to form a first etch stop film 810 and a second etch stop film 820 (refer to FIG. 10B). The first etch stop film 810 may cover a portion of the upper surface (e.g., the second upper surface 512a2 of FIG. 3C) and the outer sidewall 510c of the outermost first conductive pattern 510X as well as a portion of the inorganic insulating layer 300 in the emission area R10 and the first encapsulation area R11 of the substrate 100. The etch stop film 800 in the second encapsulation area R12 of the substrate 100 may be removed by the third etching process to expose the second organic insulating layer OL2. The second etch stop film 820 may be provided in the connection area R2 of the substrate 100 to cover another portion of the inorganic insulating layer 300 and the second conductive patterns 520. The second etch stop film 820 may be spaced apart from the first etch stop film 810. Accordingly, a portion of the upper surface of the inorganic insulating layer 300 may be exposed in the first encapsulation area R11 of the substrate 100, as shown in FIG. 10B. The third etching process may be performed in a single process with the second etching process, or may be performed in a separate process.

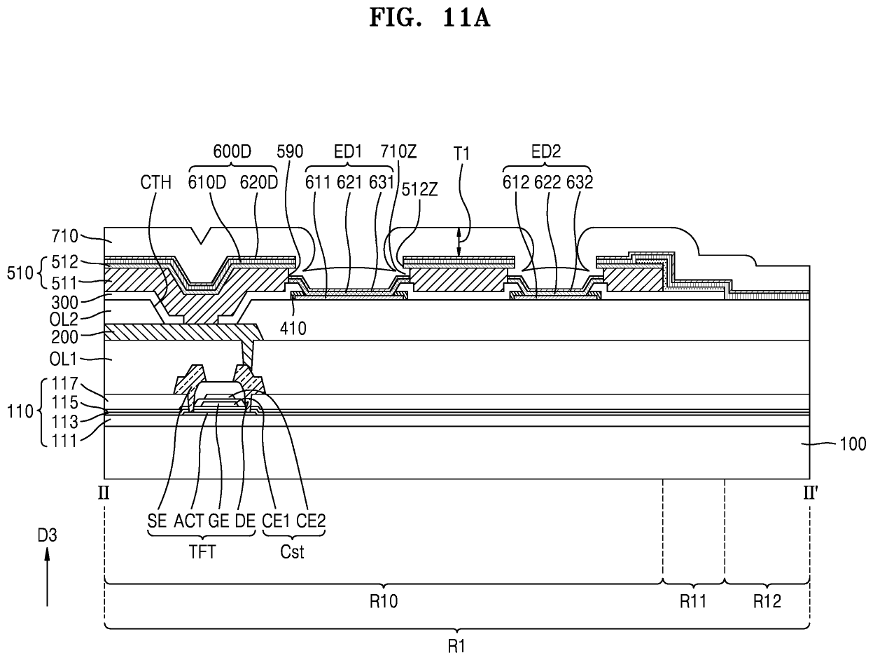

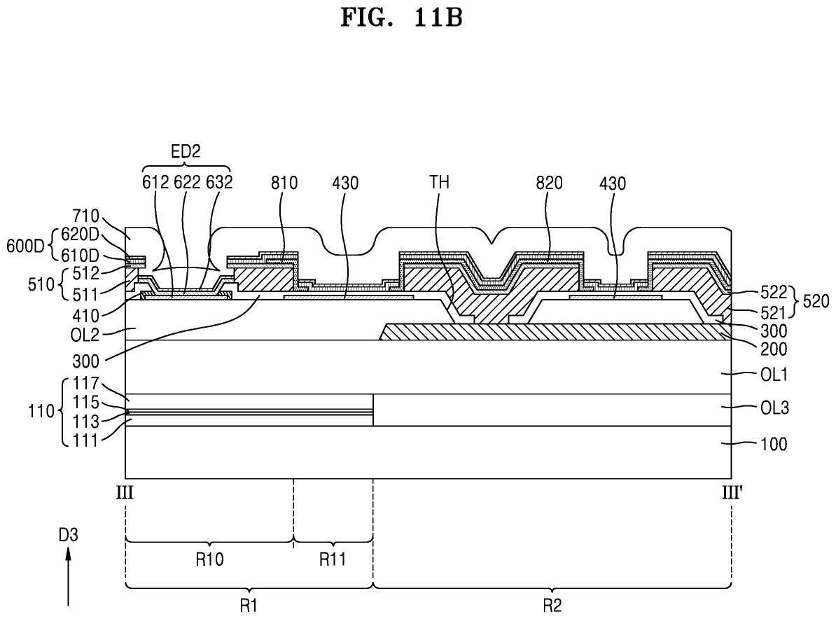

Referring to FIGS. 11A and 11B, the first intermediate layer 621, the second intermediate layer 622, the first upper electrode 631, the second upper electrode 632, and the dummy pattern 600D may be formed. The first and second intermediate layers 621 and 622 may be formed in the pixel openings 590 to respectively cover upper surfaces of corresponding first and second lower electrodes 611 and 612. The first and second upper electrodes 631 and 632 may be formed in the pixel openings 590 to respectively cover upper surfaces of the first and second intermediate layers 621 and 622. Accordingly, the manufacturing of the first light-emitting device ED1 and the second light-emitting device ED2 may be completed.

The dummy upper electrode 620D may be formed in the emission area R10, the first and second encapsulation areas R11 and R12, and the connection area R2 of the substrate 100. The dummy pattern 600D may be formed on the first upper conductive pattern 512 and the first etch stop film 810 in the emission area R10 of the substrate 100. The dummy pattern 600D may include the dummy intermediate layer 610D and the dummy upper electrode 620D. The dummy intermediate layer 610D may be formed in a single process with the first functional layer of the first intermediate layer 621 and the second functional layer of the second intermediate layer 622. The first function layer, the second functional layer, and the dummy intermediate layer 610D may be formed by a deposition process. The dummy upper electrode 620D may be formed by a single process with the first upper electrode 631 and the second upper electrode 632. The dummy upper electrode 620D, the first upper electrode 631, and the second upper electrode 632 may be formed by a deposition process, for example. The dummy pattern 600D on an upper surface of the first conductive pattern 510 may be spaced apart from the first and second intermediate layers 621 and 622 and the first and second upper electrodes 631 and 632 by the tip portions 512Z of the first upper conductive pattern 512.

The dummy pattern 600D may cover the upper surface of the second organic insulating layer OL2 in the first and second encapsulation areas R11 and R12 of the substrate 100. The dummy pattern 600D may cover the second etch stop film 820 in the connection area R2 of the substrate 100. As shown in FIG. 11B, the dummy upper electrode 620D may cover the exposed upper surface of the inorganic insulating layer 300 in the first encapsulation area R11 of the substrate 100.

The first inorganic encapsulation layer 710 may be formed in the emission area R10, the first and second encapsulation areas R11 and R12, and the connection area R2 of the substrate 100 to cover the first and second upper electrodes 631 and 632 and the dummy upper electrode 620D. The first inorganic encapsulation layer 710 may further extend into the pixel openings 590 to form the inorganic bonding portions 710Z. The first inorganic encapsulation layer 710 may be formed by a deposition process such as CVD.

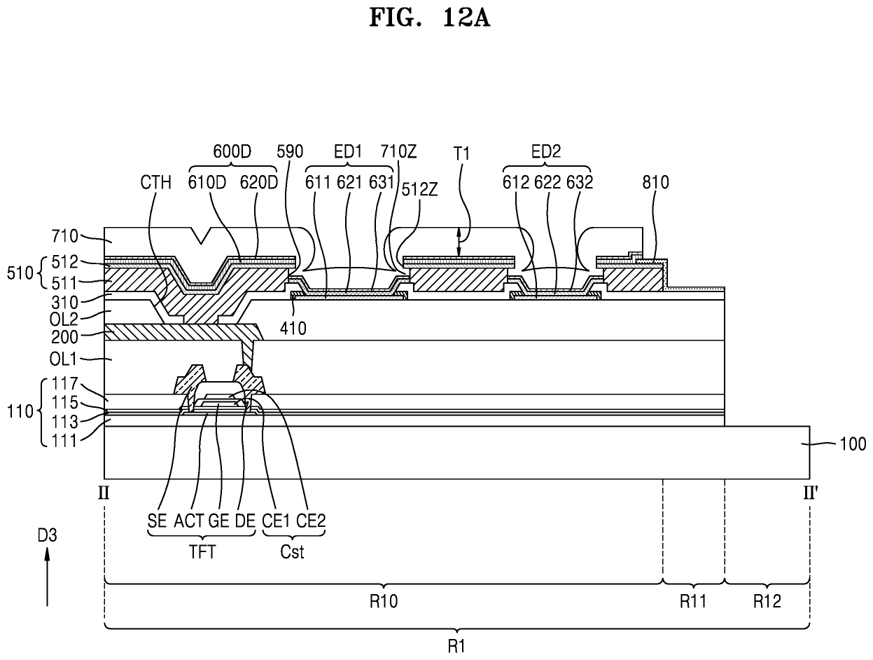

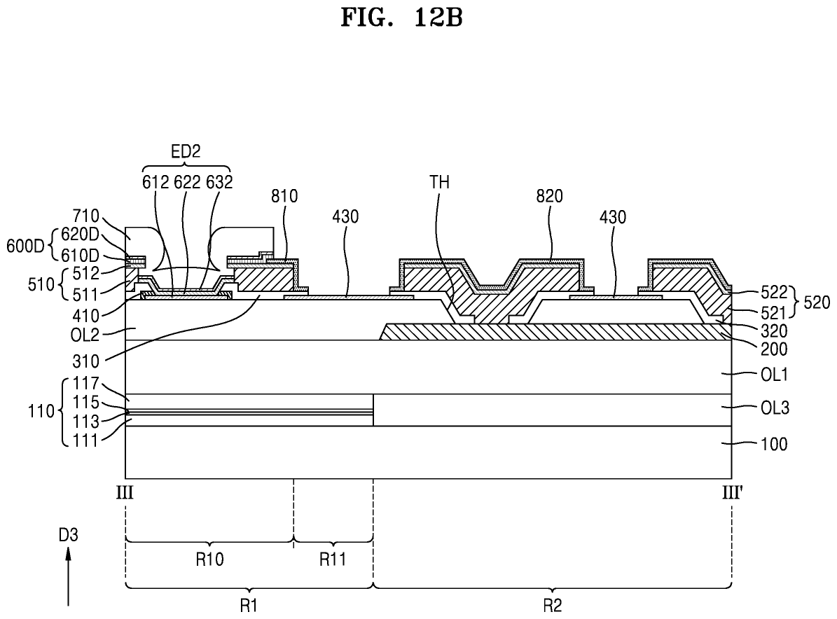

Referring to FIGS. 12A and 12B, a third photoresist pattern (not shown) may be formed on the first inorganic encapsulation layer 710 in the emission area R10 of the substrate 100. The third photoresist pattern may be formed by a photolithography process. A portion of the first inorganic encapsulation layer 710 in the first and second encapsulation areas R11 and R12 and the connection area R2 of the substrate 100 may be exposed by the third photoresist pattern. The exposed portion of the first inorganic encapsulation layer 710 may be removed by an etching process. The dummy pattern 600D on a lower surface of the removed portion of the first inorganic encapsulation layer 710 may be further etched. Accordingly, the first etch stop film 810 and the second etch stop film 820 may be exposed. The etching of the first inorganic encapsulation layer 710 may be a dry etching process, but is not limited thereto.

A portion of the inorganic insulating layer 300, which is exposed by the first etch stop film 810 and the second etch stop film 820, may be removed by the etching process, and the first inorganic insulating layer 310 and the second inorganic insulating layer 320, which are spaced apart from each other as shown in FIG. 12B, may be formed. The first inorganic insulating layer 310 and the second inorganic insulating layer 320 may expose the lower protective layer 430. The etching of the first inorganic insulating layer 310 may be performed by a dry etching process, but is not limited thereto.

Then, as shown in FIG. 12A, the stacked structure 110, the first organic insulating layer OL1, and the second organic insulating layer OL2 in the second encapsulation area R12 of the substrate 100 may be removed by an etching process to expose an upper surface of the substrate 100 in the second encapsulation area R12. In an etching process of the first and second organic insulating layers OL1 and OL2, the first etch stop film 810 and the second etch stop film 820 may have etch selectivity. The first conductive pattern 510 may not be exposed to the etching process by the first etch stop film 810. The second conductive patterns 520 may not be exposed to the etching process by the second etch stop film 820.

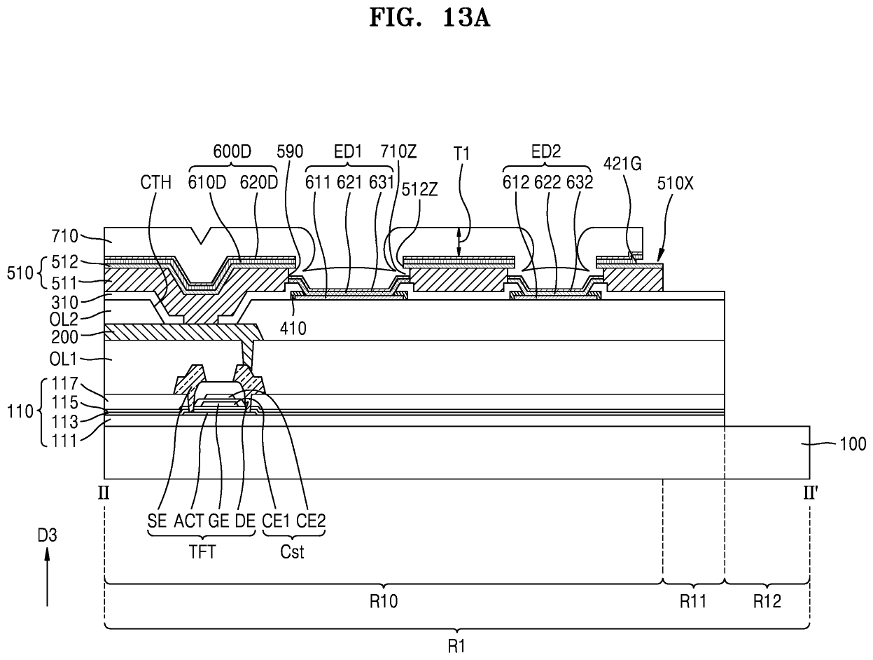

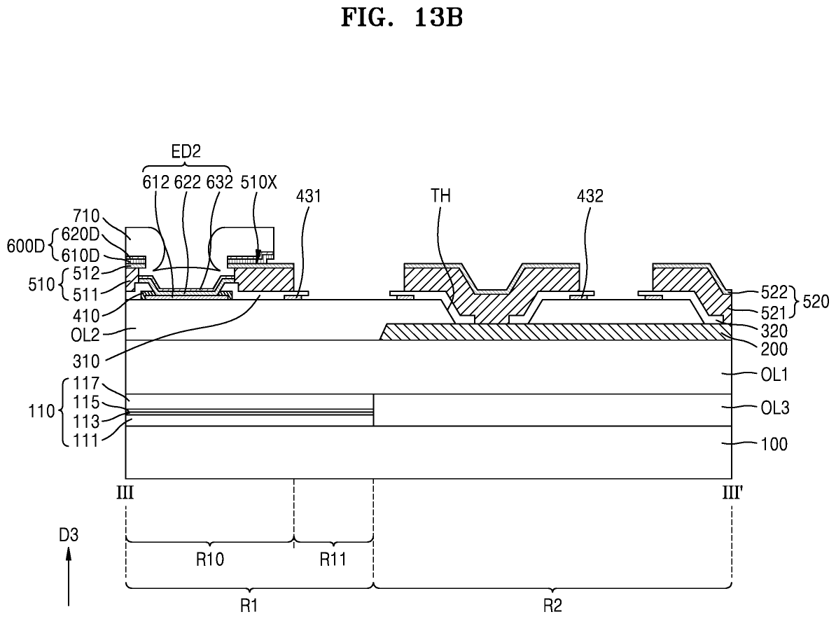

Referring to FIGS. 13A and 13B, the first etch stop film 810 and the second etch stop film 820 may be removed by an etching process. The etching process may be a wet etching process, for example. A first gap area 421G may be defined between the outermost first conductive pattern 510X and the dummy pattern 600D by the removal of the first etch stop film 810. Also, a portion of the outermost first conductive pattern 510X and the first inorganic insulating layer 310 in the first encapsulation area R11 of the substrate 100 may be exposed.

As shown in FIG. 13B, the second etch stop film 820 may be removed to expose the second organic insulating layer OL2 in the first encapsulation area R11 of the substrate 100 and expose the second conductive patterns 520 in the connection area R2 of the substrate 100. At this time, a portion of the first inorganic insulating layer 310 and a portion of the second inorganic insulating layer 320 may be further exposed.

An exposed portion of the lower protective layer 430 may be removed to form the first lower protective pattern 431 and the second lower protective patterns 432, which are spaced apart from each other. The first lower protective pattern 431 and the second lower protective patterns 432 are as described with reference to FIG. 3D. The removal of the lower protective layer 430 may be performed by a single process with the removal of the first and second etch stop films 810 and 820 or may be performed by a separate process. A first lower gap area may be defined between the second organic insulating layer OL2 and the first inorganic insulating layer 310 to expose an outer sidewall of the first lower protective pattern 431. Second lower gap areas may be defined between the second organic insulating layer OL2 and the second inorganic insulating layer 320 to expose outer sidewalls of the second lower protective patterns 432.

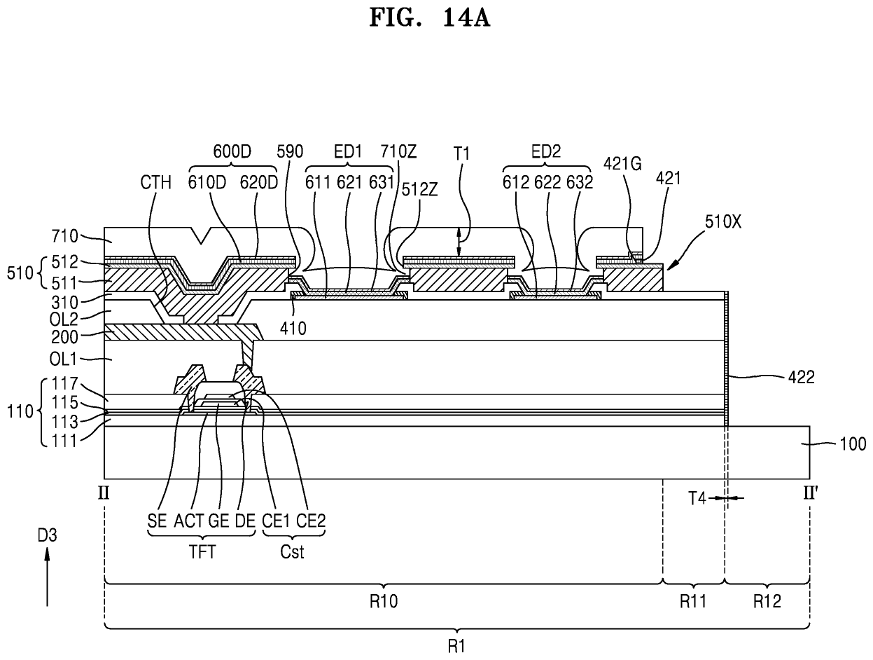

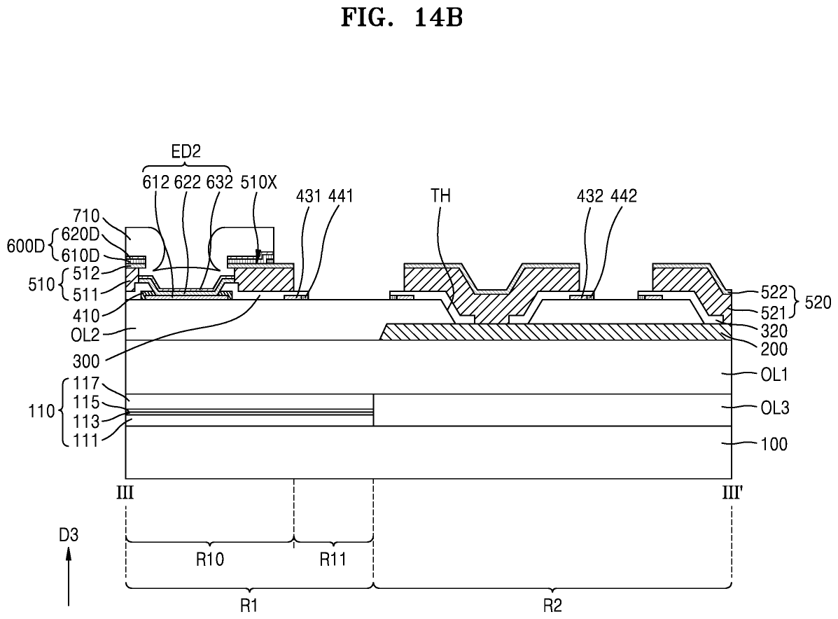

Referring to FIGS. 14A and 14B, the first inorganic pattern 421, the second inorganic pattern 422, the first gap fill pattern 441, and the second gap fill patterns 442 may be formed. The first inorganic pattern 421 may be provided in the emission area R10 of the substrate 100, and may fill the first gap area 421G (refer to FIGS. 13A and 13B). The second inorganic pattern 422 may be provided in the second encapsulation area R12 of the substrate 100, and may cover an outer sidewall of the first inorganic insulating layer 310, an outer sidewall of the second organic insulating layer OL2, an outer sidewall of the first organic insulating layer OL1, and an outer sidewall of the stacked structure 110. The first gap fill pattern 441 may be formed in the first lower gap area, and the second gap fill patterns 442 may be provided in the second lower gap areas.

The forming of the first inorganic pattern 421, the second inorganic pattern 422, the first gap fill pattern 441, and the second gap fill patterns 442 may include forming an inorganic film in the emission area R10, the first and second encapsulation areas R11 and R12, and the connection area R2 of the substrate 100 by a deposition process and patterning the inorganic film by an etching process. The etching process may be a dry etching process. The inorganic film may be formed by a deposition process such as CVD. Accordingly, the thickness T4 of the second inorganic pattern 422 may be less than the thickness T41 (refer to FIG. 3C) of the first inorganic pattern 421.

Referring to FIGS. 3B and 3D again, the second inorganic encapsulation layer 720 may be formed in the emission area R10, the first and second encapsulation areas R11 and R12, and the connection area R2 of the substrate 100. The arrangement of the second inorganic encapsulation layer 720 may be as described above. The second inorganic encapsulation layer 720 may be formed by a deposition process such as CVD. Accordingly, the second horizontal thickness T22 of the second inorganic encapsulation layer 720 may be less than the second vertical thickness T2 thereof. The manufacturing of the display apparatus 1 as described in FIGS. 3A to 3D may be completed by the examples described above.

Unlike the above description, before the second inorganic encapsulation layer 720 is formed, the organic encapsulation layer 730 may be further formed. In this case, the display apparatus 1 as described in FIGS. 4A and 4B may be manufactured.

Accordingly to embodiments, a fine metal mask may not be used in a manufacturing process of the display apparatus 1. Instead, a photolithography process of forming a photoresist pattern by the photolithography process and an etching process using the photoresist pattern may be performed. Accordingly, margins for forming components may be reduced. Limitations on the planar arrangements and areas of the first to third light-emitting devices ED1, ED2, and ED3 may be reduced to improve the design freedom of the first to third light-emitting devices ED1, ED2, and ED3. Accordingly, the resolution of the display apparatus 1 may be increased. The manufacturing efficiency of the display apparatus 1 may be improved.

According to the disclosure, a display apparatus may show improved stretchable characteristics in a connection area of a substrate thereof. Accordingly, the display apparatus may show improved stretchable, flexible, rollable, and bendable characteristics.

The display apparatus may be manufactured by a photolithography process and an etching process. Accordingly, margins for forming components of the display apparatus may be reduced, and limitations on the arrangements and areas of the light-emitting devices may be reduced. By embodiments, the resolution of the display apparatus may be improved.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the claims.

What is claimed is:

1. A display apparatus comprising:
a substrate comprising an emission area and an encapsulation area surrounding the emission area;
a first lower conductive pattern provided in the emission area of the substrate and defining a pixel opening;
a light-emitting device in the pixel opening of the first lower conductive pattern;
a first upper conductive pattern on the first lower conductive pattern, the first upper conductive pattern including:
a tip portion protruding from an upper surface of the first lower conductive pattern toward the pixel opening of the first lower conductive pattern; and
an outermost first upper conductive pattern disposed between the light-emitting device and the encapsulation area of the substrate in a plan view; and
a dummy pattern on the first upper conductive pattern,
wherein the dummy pattern covers a first upper surface of the outermost first upper conductive pattern in the plan view and is spaced apart from a second upper surface of the outermost first upper conductive pattern, and
the second upper surface of the outermost first upper conductive pattern is connected to the first upper surface of the outermost first upper conductive pattern and is disposed between the first upper surface of the outermost first upper conductive pattern and the encapsulation area of the substrate in the plan view.

2. The display apparatus of claim 1, wherein the tip portion of the first upper conductive pattern is provided in the emission area of the substrate and is not provided in the encapsulation area of the substrate.

3. The display apparatus of claim 1, further comprising:
a first inorganic encapsulation layer provided on the first upper conductive pattern and covering the light-emitting device; and
a second inorganic encapsulation layer on the first inorganic encapsulation layer,
wherein the first inorganic encapsulation layer is disposed on the first upper surface of the outermost first upper conductive pattern but is spaced apart from the second upper surface of the outermost first upper conductive pattern.

4. The display apparatus of claim 3, wherein the first inorganic encapsulation layer is spaced apart from the encapsulation area of the substrate, and
the second inorganic encapsulation layer extends to the encapsulation area of the substrate.

5. The display apparatus of claim 4, wherein the second inorganic encapsulation layer covers the second upper surface of the outermost first upper conductive pattern.

6. The display apparatus of claim 4, wherein the substrate further comprises a connection area, and a portion of the encapsulation area is disposed between the emission area and the connection area,
the light-emitting device, the first inorganic encapsulation layer, and the first lower conductive pattern are spaced apart from the connection area of the substrate, and
the second inorganic encapsulation layer extends to the connection area of the substrate.

7. The display apparatus of claim 6, further comprising:
a second lower conductive pattern disposed in the connection area of the substrate and spaced apart from the first lower conductive pattern; and
a second upper conductive pattern disposed on the second lower conductive pattern and spaced apart from the first upper conductive pattern,
wherein the second lower conductive pattern comprises a same material as a material of the first lower conductive pattern, and
the second upper conductive pattern comprises a same material as a material of the first upper conductive pattern.

8. The display apparatus of claim 1, further comprising an organic insulating layer between the substrate and the first lower conductive pattern,
wherein the encapsulation area comprises a first encapsulation area and a second encapsulation area, and the first encapsulation area is disposed between the emission area and the second encapsulation area, and
the organic insulating layer is provided in the emission area and the first encapsulation area of the substrate but is spaced apart from the second encapsulation area of the substrate.

9. The display apparatus of claim 8, further comprising an inorganic insulating layer between the organic insulating layer and the first lower conductive pattern,
wherein the inorganic insulating layer is provided in the emission area and the first encapsulation area of the substrate and is spaced apart from the second encapsulation area of the substrate.

10. The display apparatus of claim 8, further comprising a first inorganic pattern provided between the outermost first upper conductive pattern and an end portion of the dummy pattern,
wherein the dummy pattern is provided on an inner side surface of the first inorganic pattern.

11. The display apparatus of claim 10, further comprising a second inorganic pattern provided on a sidewall of the organic insulating layer,
wherein the second inorganic pattern comprises a same material as a material of the first inorganic pattern, and
a thickness of the second inorganic pattern is less than a thickness of the first inorganic pattern.

12. A display apparatus comprising:
a substrate comprising island areas and a connection area between the island areas, wherein each of the island areas comprises an emission area and an encapsulation area;
an inorganic insulating layer on the substrate;
a first conductive pattern provided on the inorganic insulating layer in the island areas of the substrate and defining pixel openings;
light-emitting devices provided in the pixel openings of the first conductive pattern;
a first inorganic encapsulation layer sealing the light-emitting devices in the emission area of the substrate, the inorganic insulating layer comprising:
a first inorganic insulating layer provided in each of the island areas of the substrate; and
a second inorganic insulating layer provided in the connection area of the substrate and spaced apart from the first inorganic insulating layer; and
a second inorganic encapsulation layer on the first inorganic encapsulation layer,
wherein the first inorganic encapsulation layer is spaced apart from the encapsulation area and the connection area of the substrate, and
the second inorganic encapsulation layer is provided in the emission area, the encapsulation area, and the connection area of the substrate.

13. The display apparatus of claim 12, wherein a first thickness of the first inorganic encapsulation layer is greater than a second vertical thickness of the second inorganic encapsulation layer and a third thickness of the first inorganic insulating layer, and
the second vertical thickness is greater than the third thickness.

14. The display apparatus of claim 12, further comprising a second conductive pattern provided in the connection area of the substrate and covering the second inorganic insulating layer,
wherein the second conductive pattern is spaced apart from the first conductive pattern and comprises a same material as a material of the first conductive pattern.

15. The display apparatus of claim 14, wherein a plurality of second conductive patterns are provided in the connection area of the substrate, and the plurality of second conductive patterns are spaced apart from each other.

16. The display apparatus of claim 15, wherein a plurality of second inorganic insulating layers are provided in the connection area of the substrate, and the plurality of second inorganic insulating layers are spaced apart from each other, and
the plurality of second conductive patterns are respectively provided on the plurality of second inorganic insulating layers.

17. The display apparatus of claim 12, further comprising:
an organic insulating layer disposed in the emission area and the encapsulation area of the substrate; and
a second inorganic pattern provided on a sidewall of the organic insulating layer,
wherein the first inorganic insulating layer is disposed on the organic insulating layer, and
the second inorganic pattern does not extend onto an upper surface of the first inorganic insulating layer.

18. The display apparatus of claim 17, wherein the second inorganic encapsulation layer extends onto the sidewall of the organic insulating layer, and
the second inorganic pattern is between the sidewall of the organic insulating layer and the second inorganic encapsulation layer.

19. The display apparatus of claim 18, wherein the second inorganic encapsulation layer comprises:
a second vertical thickness from an upper surface of the first conductive pattern; and
a second horizontal thickness from a sidewall of the second inorganic pattern,
wherein the second horizontal thickness of the second inorganic encapsulation layer is greater than a thickness of the second inorganic pattern.

20. The display apparatus of claim 19, wherein a sum of a first thickness of the first inorganic encapsulation layer and the second vertical thickness of the second inorganic encapsulation layer is greater than a sum of the second horizontal thickness of the second inorganic encapsulation layer and the thickness of the second inorganic pattern.
